(19) United States
(12) Patent Application Publication
(10) Pub. No.: US 2024/0322819 A1
(43) Pub. Date: Sep. 26, 2024

(54) FINE GRAIN POWER GATING

(71) Applicant: QUALCOMM Incorporated, San Diego, CA (US)

(72) Inventors: Giby SAMSON, San Diego, CA (US); Ramaprasath VILANGUDIPITCHAI, San Diego, CA (US); Pavan Kumar PATIBANDA, San Diego, CA (US); Joshua ONG, Oceanside, CA (US); Chethan SWAMYNATHAN, Bangalore (IN); Vajram GHANTASALA, San Jose, CA (US); Venugopal BOYNAPALLI, San Diego, CA (US); Madan KRISHNAPPA, San Diego, CA (US); Vineet OORAMKUMARATH, San Diego, CA (US); Mohamed Saud MUSLIYARAKATH, Temecula, CA (US)

(21) Appl. No.: 18/188,656

(22) Filed: Mar. 23, 2023

(51) Int. Cl. H03K 17/687; H03K 3/012; H03K 3/3562

(52) U.S. Cl. CPC H03K 17/6872; H03K 3/012; H03K 3/35625

(57) ABSTRACT

Aspects of the present disclosure provide cells including integrated switches and/or integrated clamps. In some aspects, a cell includes a circuit having an input and an output, and a switch coupled between a supply rail and the circuit, wherein the switch is configured to receive an enable signal, turn on when the enable signal has a first logic value, and turn off when the enable signal has a second logic value. The cell also includes a first clamp coupled to the output of the circuit, wherein the first clamp is configured to clamp the output of the circuit when the enable signal has the second logic value.

### BACKGROUND

### Field

Aspects of the present disclosure relate generally to power management, and more particularly, to power gating.

### Background

Circuits on a chip (e.g., system on a chip (SoC)) receive power from a power source (e.g., a battery or another power source). The chip may employ power gating to reduce power consumption by gating power (i.e., switching off power) to a circuit on the chip when the circuit is inactive (i.e., not in use). To implement power gating, the chip may include one or more switches (e.g., globally distributed head switches (GHDS)) between the power source and the circuit. To gate power to the circuit when the circuit is inactive, a power manager turns off the one or more switches. This prevents leakage current from flowing through the circuit when the circuit is inactive, which significantly reduces power consumption due to leakage current.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a cell. The cell includes a circuit having an input and an output, and a switch coupled between a supply rail and the circuit, wherein the switch is configured to receive an enable signal, turn on when the enable signal has a first logic value, and turn off when the enable signal has a second logic value. The cell also includes a first clamp coupled to the output of the circuit, wherein the first clamp is configured to clamp the output of the circuit when the enable signal has the second logic value.

A second aspect relates to a cell. The cell includes a circuit having an input and an output, and a switch coupled between the circuit and a ground, wherein the switch is configured to receive an enable signal, turn on when the enable signal has a first logic value, and turn off when the enable signal has a second logic value. The cell includes a first clamp coupled to the output of the circuit, wherein the first clamp is configured to clamp the output of the circuit when the enable signal has the second logic value.

A third aspect relates to a cell. The cell includes one or more flip-flops, and a switch coupled between a supply rail and the one or more flip-flops, wherein the switch is configured to receive an enable signal, turn on when the enable signal has a first logic value, and turn off when the enable signal has a second logic value.

### BRIEF DESCRIPTION OF THE DRAWINGS

FIG. 1 shows an example of a system employing coarse power gating according to certain aspects of the present disclosure.

FIG. 2 is a timing diagram illustrating an example of leakage current in the circuit shown in FIG. 1 according to certain aspects of the present disclosure.

FIG. 3A shows an example of a system employing fine power gating according to certain aspects of the present disclosure.

FIG. 3B shows another example of a system employing fine power gating according to certain aspects of the present disclosure.

FIG. 4A is a timing diagram illustrating an example of leakage current in the circuit shown in FIG. 3A according to certain aspects of the present disclosure.

FIG. 4B is a timing diagram illustrating an example of leakage current in the circuit shown in FIG. 3B according to certain aspects of the present disclosure.

FIG. 5 shows an example of an isolation cell between two power-gating domains according to certain aspects of the present disclosure.

FIG. 6 shows an example in which circuits in different power-gating domains are scattered on a chip according to certain aspects of the present disclosure.

FIG. 7A shows an example of a cell including a switch and a clamp according to certain aspects of the present disclosure.

FIG. 7B shows another example of a cell including a switch and a clamp according to certain aspects of the present disclosure.

FIG. 7C shows an example of a cell including multiple clamps according to certain aspects of the present disclosure.

FIG. 7D shows an example of a cell including a switch and a clamp including a p-type field effect transistor according to certain aspects of the present disclosure.

FIG. 7E shows an example of a cell including a switch, a clamp, and buffers according to certain aspects of the present disclosure.

FIG. 7F shows an example of a cell including multiple clamps including respective PFETs according to certain aspects of the present disclosure.

FIG. 7G shows an example of a cell including buffers and multiple clamps according to certain aspects of the present disclosure.

FIG. 7H shows an example of a cell including a switch and a clamp including an n-type field effect transistor according to certain aspects of the present disclosure.

FIG. 7I shows another example of a cell including a switch, a clamp, and buffers according to certain aspects of the present disclosure.

FIG. 7J shows another example of a cell including multiple clamps according to certain aspects of the present disclosure.

FIG. 7K shows another example of a cell including buffers and multiple clamps according to certain aspects of the present disclosure.

FIG. 7L shows an example of a cell including a switch and two clamps according to certain aspects of the present disclosure.

FIG. 7M shows an example of a cell and a switch located outside the cell according to certain aspects of the present disclosure.

FIG. 7N shows another example of a cell including multiple clamps according to certain aspects of the present disclosure.

FIG. 7O shows another example of a cell including a clamp including a PFET according to certain aspects of the present disclosure.

FIG. 7P shows another example of a cell including a clamp including an NFET according to certain aspects of the present disclosure.

FIG. 7Q shows an example of a circuit including multiple cells according to certain aspects of the present disclosure.

FIG. 7R shows an exemplary implementation of multiple cells in a circuit according to certain aspects of the present disclosure.

FIG. 8A shows an example of a cell including flip-flops and a switch according to certain aspects of the present disclosure.

FIG. 8B shows another example of a cell including flip-flops and a switch according to certain aspects of the present disclosure.

FIG. 8C shows an example of a cell including flip-flops, a switch, and multiple clamps according to certain aspects of the present disclosure.

FIG. 8D shows an example of a cell including flip-flops, a switch, and a clamp according to certain aspects of the present disclosure.

FIG. 8E shows an example of a switch and a circuit including multiple cells according to certain aspects of the present disclosure.

FIG. 8F shows an example of a circuit including multiple cells according to certain aspects of the present disclosure.

FIG. 9A shows an exemplary layout for a cell according to certain aspects of the present disclosure.

FIG. 9B shows an example of a second cell next to the cell in FIG. 9A according to certain aspects of the present disclosure.

FIG. 9C shows another exemplary layout for a cell according to certain aspects of the present disclosure.

FIG. 9D shows yet another exemplary layout for a cell according to certain aspects of the present disclosure.

FIG. 9E shows still another exemplary layout for a cell according to certain aspects of the present disclosure.

FIG. 10A shows an example of a cell bounded by dummy gates according to certain aspects of the present disclosure.

FIG. 10B shows another example of a cell bounded by dummy gates according to certain aspects of the present disclosure.

FIG. 11 shows an example of a system in which cells according to certain aspects of the present disclosure may be used.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

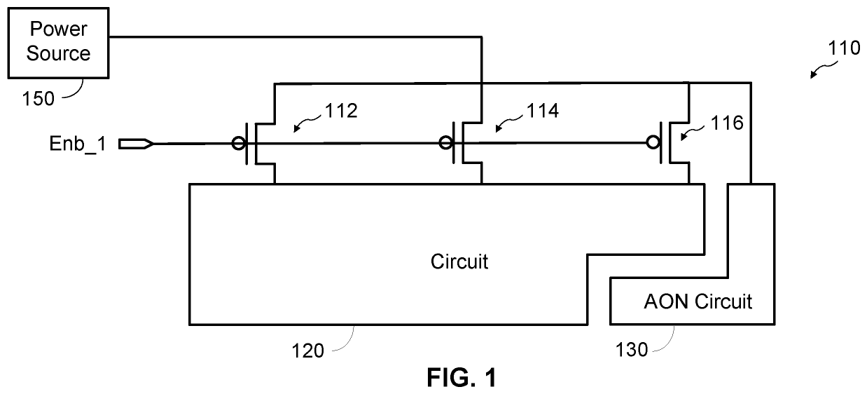

FIG. 1 shows an example of a system 110 employing coarse power gating according to certain aspects of the present disclosure. In this example, the system 110 includes a circuit 120 that can be power gated when the circuit 120 is inactive (i.e., not in use). The system also includes a first switch 112, a second switch 114, and a third switch 116 for power gating the circuit 120. Each of the switches 112, 114, and 116 is coupled between a power source 150 and the circuit 120. The power source 150 may include a battery, one or more voltage regulators (e.g., a switching regulator and/or a low dropout (LDO) regulator), a power management integrated circuit (PMIC), or any combination thereof. The system 110 may also include an always-on (AON) circuit 130 coupled to the power source 150.

The on/off states of the switches 112, 114, and 116 are controlled by an enable signal Enb_1 from a power manager (not shown). In the example in FIG. 1, each of the switches 112, 114, and 116 is implemented with a respective p-type field effect transistor (PFET). Thus, in this example, each of the switches 112, 114, and 116 turns on when the enable signal Enb_1 is low and turns off when the enable signal Enb_1 is high. However, it is to be appreciated that the present disclosure is not limited to this example.

In this example, the power manager (not shown) turns on the switches 112, 114, and 116 using the enable signal Enb_1 when the circuit 120 is active. This allows the power source 150 to provide power to the circuit 120 through the switches 112, 114, and 116. The power manager turns off the switches 112, 114, and 116 using the enable signal Enb_1 when the circuit 120 is inactive (i.e., not in use). This prevents leakage current from flowing through the circuit 120, which significantly reduces power consumption due to leakage current.

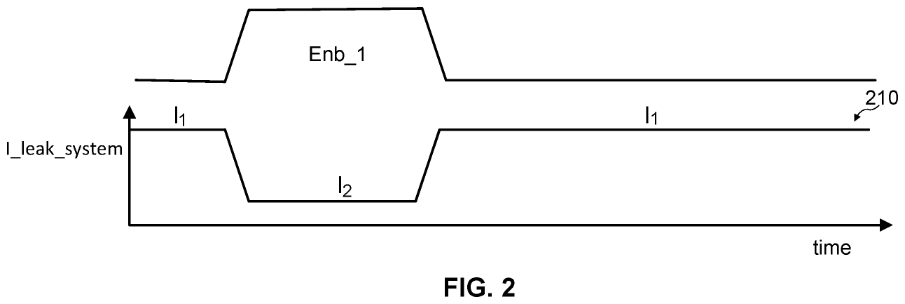

FIG. 2 is a timing diagram showing an example of the leakage current 210 of the system 110 over time. FIG. 2 also shows an example of the enable signal Enb_1. In this example, the switches 112, 114, and 116 are turned on when the enable signal Enb_1 is low. When the switches 112, 114, and 116 are turned on, the leakage current 210 is approximately I₁ in this example. The switches 112, 114, and 116 are turned off when the enable signal Enb_1 is high. For example, the power manager may assert the enable signal Enb_1 high to gate the power to circuit 120 when the circuit 120 is inactive. Turning off the switches 112, 114, and 116 prevents leakage current from flowing through the circuit 120, which reduces the leakage current 210 of the system 110 from I₁ to I₂, as shown in FIG. 2. The large reduction in the leakage current 210 reduces power consumption when the circuit 120 is inactive.

As the geometries of transistors in the circuit 120 scale down in advanced process node, the leakage current of the transistors (and hence the circuit 120) increases. Therefore, reducing leakage current using power gating when the circuit 120 is inactive is desirable to reduce power consumption. For the example where the circuit 120 is incorporated in a battery-powered mobile device, reducing power consumption is important to extend the battery life of the device.

A drawback of the coarse power gating illustrated in FIG. 1 is that the power gating is applied to the entire circuit 120. As a result, the entire circuit 120 needs to be inactive (i.e., not in use) in order to gate power to the circuit 120. Thus, when a first portion of the circuit 120 is inactive and a second portion of the circuit 120 is active, the power to the first portion of the circuit 120 can not be gated to reduce leakage current since power is needed for the second portion of the circuit 120, which remains active.

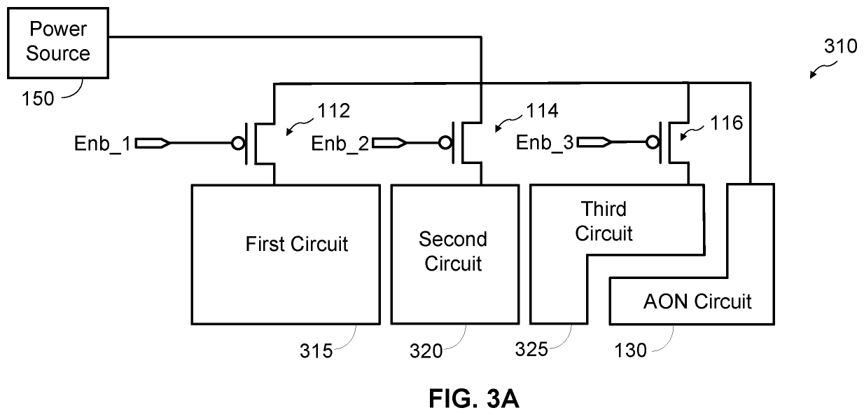

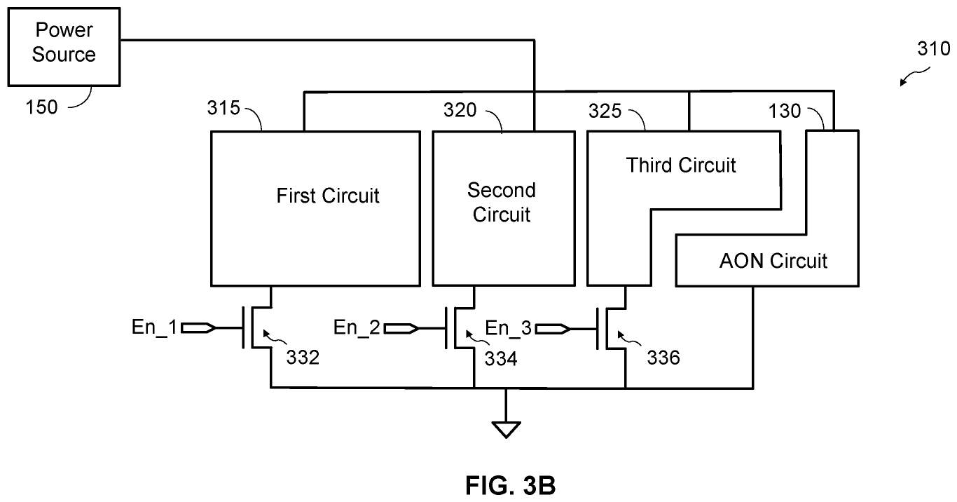

To address the above drawback of coarse power gating, fine power gating may be employed. In this regard, FIG. 3A shows an example of a system 310 employing fine power gating according to certain aspects of the present disclosure. The fine power gating provides power gating with finer granularity than the coarse power gating illustrated in FIG. 1, as discussed further below.

In this example, the circuit 120 shown in FIG. 1 is partitioned into a first circuit 315, a second circuit 320, and a third circuit 325. The first switch 112 is coupled between the power source 150 and the first circuit 315, the second switch 114 is coupled between the power source 150 and the second circuit 320, and the third switch 116 is coupled between the power source 150 and the third circuit 325. In this example, the on/off states of the switches 112, 114, and 116 are independently controlled using separate enable signals Enb_1, Enb_2, and Enb_3, respectively. This allows the power manager (not shown) to independently control power gating of the first circuit 315, the second circuit 320, and the third circuit 325.

In this example, the first circuit 315, the second circuit 320, and the third circuit 325 are in separate power-gating domains since the power gating for the first circuit 315, the second circuit 320, and the third circuit 325 can be controlled independently. More particularly, the first circuit 315 is in a first power-gating domain, the second circuit 320 is in a second power-gating domain, and the third circuit 325 is in a third power-gating domain.

For example, when the first circuit 315 is inactive and the second and third circuits 320 and 325 are active, the power manager may gate power to the first circuit 315 by turning off the first switch 112 while leaving the second and third switches 114 and 116 turned on. As a result, leakage current is reduced in the first circuit 315 while the second and third circuits 320 and 325 continue to receive power.

It is to be appreciated that the system 310 is not limited to the exemplary switches 112, 114, and 116 shown in FIG. 3A. In this regard, FIG. 3B shows an example in which the system 310 includes a first switch 332 coupled between the first circuit 315 and a ground, a second switch 334 coupled between the second circuit 320 and ground, and a third switch 336 coupled between the third circuit 325 and ground. In this example, the on/off states of the switches 332, 334, and 336 are independently controlled using separate enable signals En_1, En_2, and En_3, respectively. This allows the power manager (not shown) to independently control power gating of the first circuit 315, the second circuit 320, and the third circuit 325.

In the example in FIG. 3B, each of the switches 332, 334, and 336 is implemented with a respective n-type field effect transistor (NFET) where the respective enable signal is applied to the gate of the respective NFET. In this example, each of the switches 332, 334, and 336 turns on when the respective enable signal is high and turns off when the respective enable signal is low. The enable signals En_1, En_2, and En_3 may be the complement (i.e., inverse) of the enable signals Enb_1, Enb_2, and Enb_3 used for the switches 112, 114, and 116 in the example illustrated in FIG. 3A.

As discussed above, the power management (not shown) uses the switches 332, 334, and 336 to independently control power gating of the first circuit 315, the second circuit 320, and the third circuit 325. For example, when the first circuit 315 is inactive and the second and third circuits 320 and 325 are active, the power manager may gate power to the first circuit 315 by turning off the first switch 332 while leaving the second and third switches 334 and 336 turned on. As a result, leakage current is reduced in the first circuit 315 while the second and third circuits 320 and 325 continue to receive power.

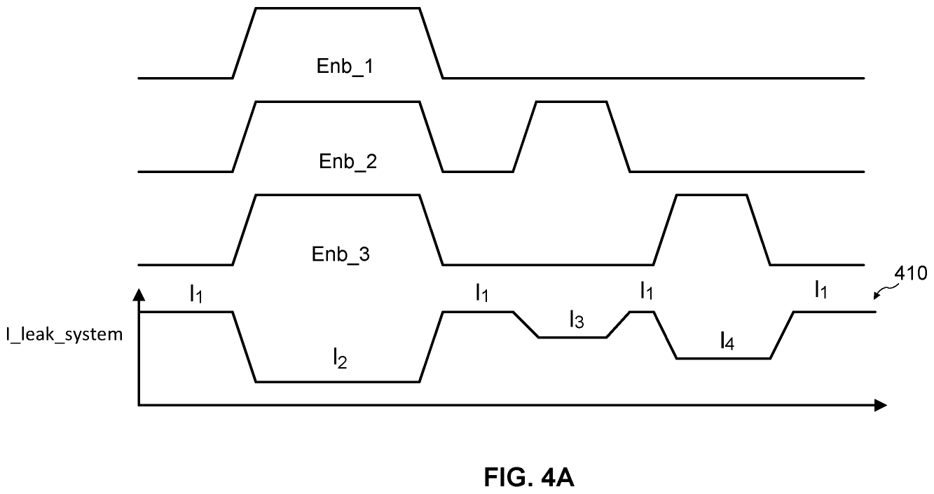

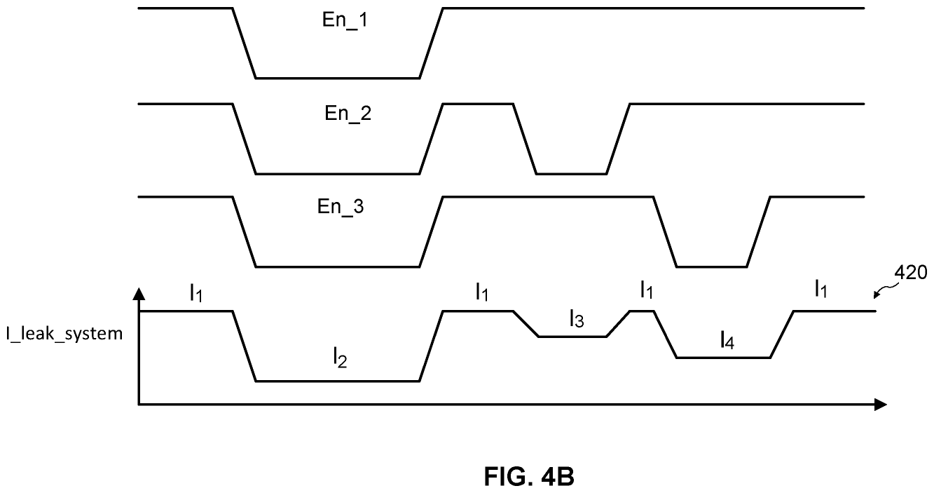

FIG. 4A is a timing diagram showing an example of the leakage current 410 of the system 310 shown in FIG. 3A over time. FIG. 4A also shows an example of the enable signals Enb_1. Enb_2, and ENb_3 which control power gating of the first circuit 315, the second circuit 320, and the third circuit 325, respectively. In this example, each of the switches 112, 114, and 116 is turned on when the respective enable signal is low, and turned off when the respective enable signal is high.

When all the switches 112, 114, and 116 are turned on, the leakage current 410 is approximately I₁ in this example. When all the switches 112, 114, and 116 are turned off (i.e., all the circuits 315, 320, and 325 are power gated), the leakage current of the system 310 is reduced from I₁ to I₂, as shown in FIG. 4A. When the second switch 114 is turned off by enable signal Enb_2 (i.e., the second circuit 320 is power gated) and the first and third switches 112 and 116 are turned on, the leakage current of the system 310 is reduced from I₁ to I₃. Note that the leakage current I₃ is greater than the leakage current I₂ since the first circuit 315 and the third circuit 325 are active in this case. When the third switch 116 is turned off by enable signal Enb_3 (i.e., the third circuit 325 is power gated) and the first and second switches 112 and 114 are turned on, the leakage current of the system 310 is reduced from I₁ to I₄. Note that the leakage current I₄ is greater than the leakage current I₂ since the first circuit 315 and the second circuit 320 are active in this case.

As shown in FIG. 4A, the fine power gating reduces the average leakage current 410 of the system 310 compared with coarse power gating shown in FIG. 2. This is because the fine power gating reduces the leakage current 410 to I₃ when the second circuit 320 is inactive and the first and third circuits 315 and 325 are active, and reduces the leakage current 410 to I₄ when the third circuit 325 is inactive and the first and second circuits 320 and 320 are active. In contrast, the coarse power gating only reduces the leakage current 210 when the entire circuit 120 is inactive.

FIG. 4B is a timing diagram showing an example of the leakage current 420 of the system 310 shown in FIG. 3B over time. FIG. 4B also shows an example of the enable signals En_1. En_2, and En_3, which are the complement of the enable signals Enb_1, Enb_2, and Enb_3 shown in FIG. 4A. As shown in FIG. 4B, the average leakage current 420 is similar to the average leakage current 410 in the example in FIG. 4A, which is smaller than the average leakage current 210 with the coarse power gating shown in FIG. 2.

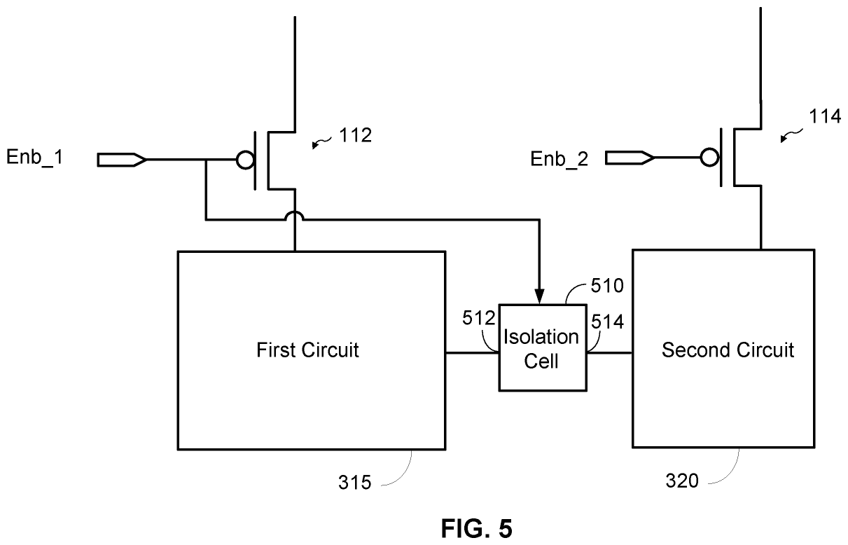

The system 310 may include one or more isolation cells between different power-gating domains. In this regard, FIG. 5 shows an example of an isolation cell 510 between the first circuit 315 and the second circuit 320, in which the first circuit 315 is in the first power-gating domain and the second circuit 320 is in the second power-gating domain. In this example, the isolation cell 510 has a first terminal 512 coupled to the first circuit 315 and a second terminal 514 coupled to the second circuit 320.

When the first circuit 315 and the second circuit 320 are both active, the isolation cell 510 is configured to pass signals from the first circuit 315 to the second circuit 320. This allows the first circuit 315 to communicate with the second circuit 320 when both circuits 315 and 320 are active. When the first circuit 315 is power gated and the second circuit 320 is active, the isolation cell holds (i.e., clamps) the terminal 514 to a defined logic state. This is done to prevent a floating voltage or an undefined logic state from being input to the second circuit 320 from the first circuit 315 when the first circuit 315 is power gated (i.e., the first switch 112 is turned off). In one example, the isolation cell 510 is configured to clamp the terminal 514 high when the first circuit 315 is power gated. In another example, the isolation cell 510 is configured to clamp the terminal 514 low when the first circuit 315 is power gated.

In some implementations, the enable signal Enb_1 may be input to the isolation cell 510. In this example, the isolation cell 510 determines when the first circuit 315 is power gated based on the logic state of the enable signal Enb_1. For example, when the enable signal Enb_1 has a logic state (e.g., high) that turns off the first switch 112, the isolation cell 510 may clamp the terminal 514 at a defined logic state (e.g., high or low). When the enable signal Enb_1 has a logic state (e.g., low) that turns on the first switch 112, the isolation cell 510 may pass signals from the first circuit 315 to the second circuit 320.

It is to be appreciated that the isolation cell 510 is not drawn to scale relative to the first circuit 315 and the second circuit 320 in FIG. 5. Although one isolation cell 510 is shown in FIG. 5 for case of illustration, it is also to be appreciated that the system 310 typically includes multiple isolation cells between the circuits 315, 320, and 325. It is also be appreciated that isolation cells may also be used for the example where the system 310 includes the switches 332, 334, and 336 for power gating.

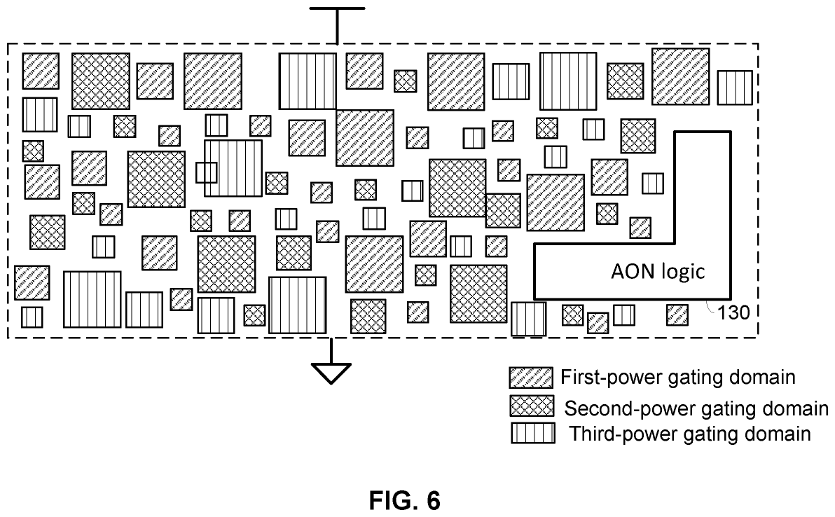

In the example shown in FIGS. 3A and 3B, circuits in the first power-gating domain are clustered into the first circuit 315, circuits in the second power-gating domain are clustered into the second circuit 320, and circuits in the third power-gating domain are clustered into the third circuit 325. However, in many cases, circuits (e.g., logic) in the different power-gating domains are scattered on the chip. In this regard, FIG. 6 shows an example in which circuits in the first power-gating domain, circuits in the second-power gating domain, and circuits in the third power-gating domain are scattered on the chip. In FIG. 6, the shading of each circuit indicates the power-gating domain of the circuit. The scattering of circuits in the different power-gating domain makes the implementation of fine power gating and cell isolation challenging.

To address this, aspects of the present disclosure provide standard cells with integrated switches and/or clamps. Because the switches and/or clamps are integrated in the standard cells, switches and/or isolation cells do not need to be laid out separately for the standard cells, which facilitates the implementation of fine power gating. In certain aspects, the standard cells may be defined in a standard cell library. For each of the standard cells, the standard cell library may specify the layout of the transistors in the standard cell. The above features and other features of the present disclosure are discussed further below.

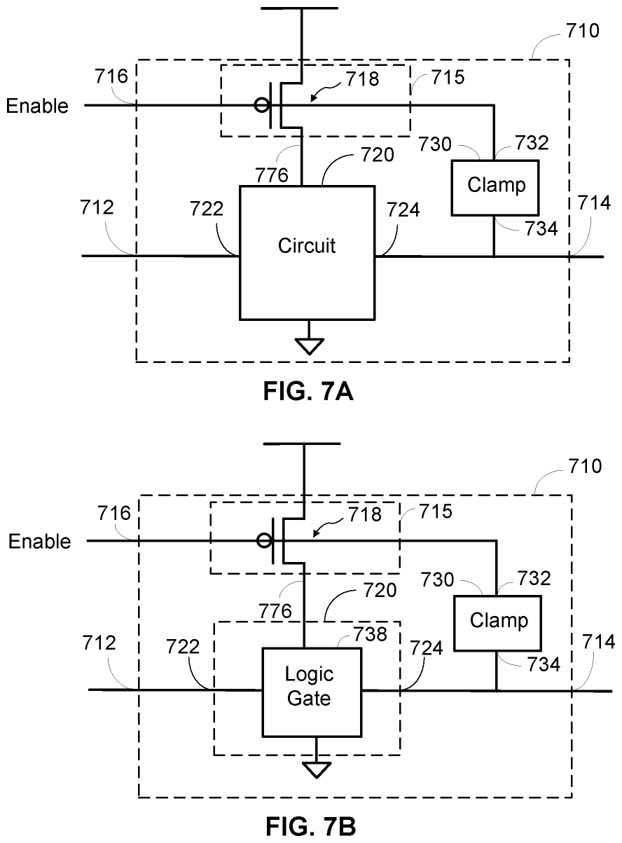

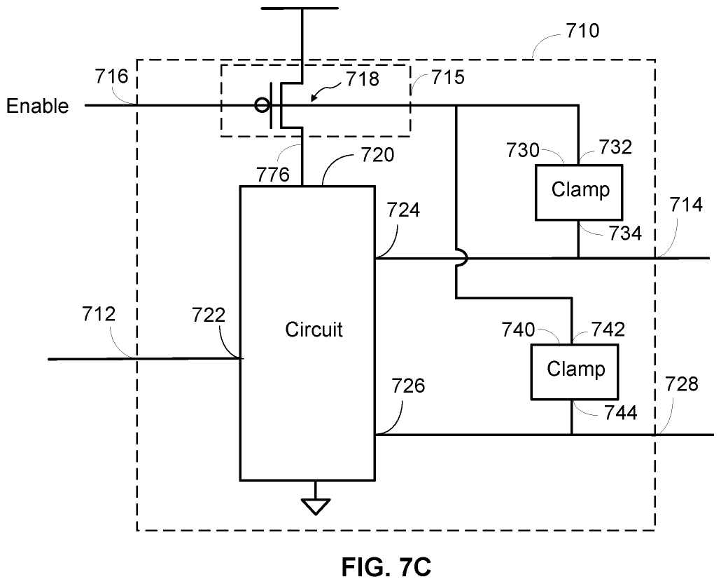

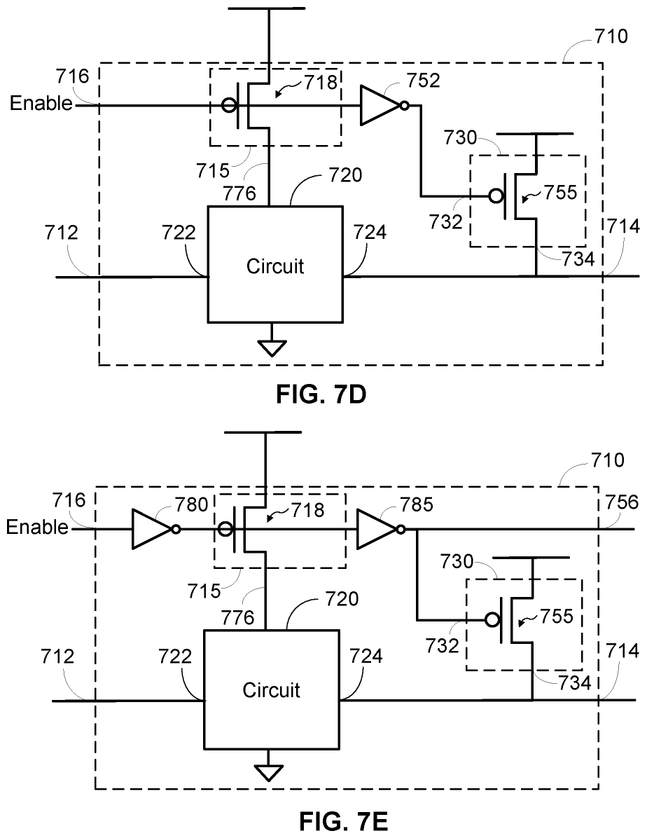

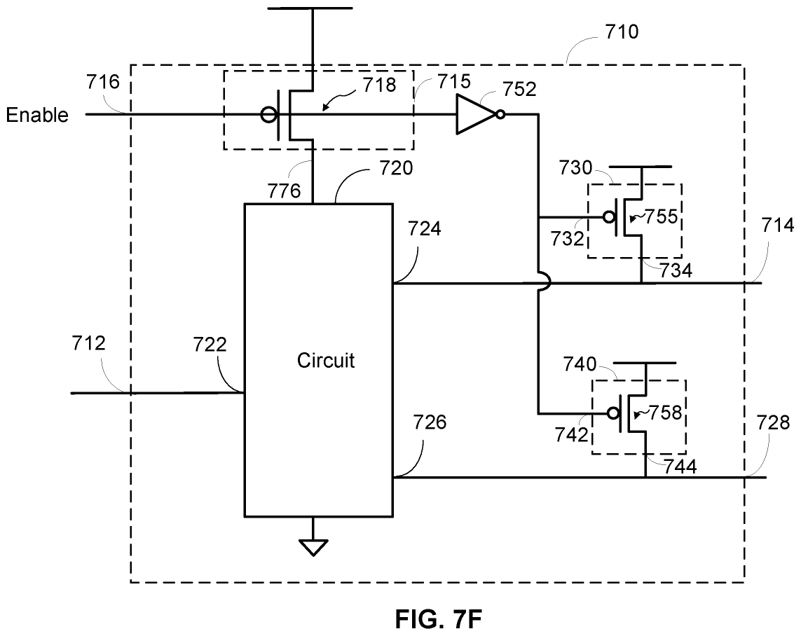

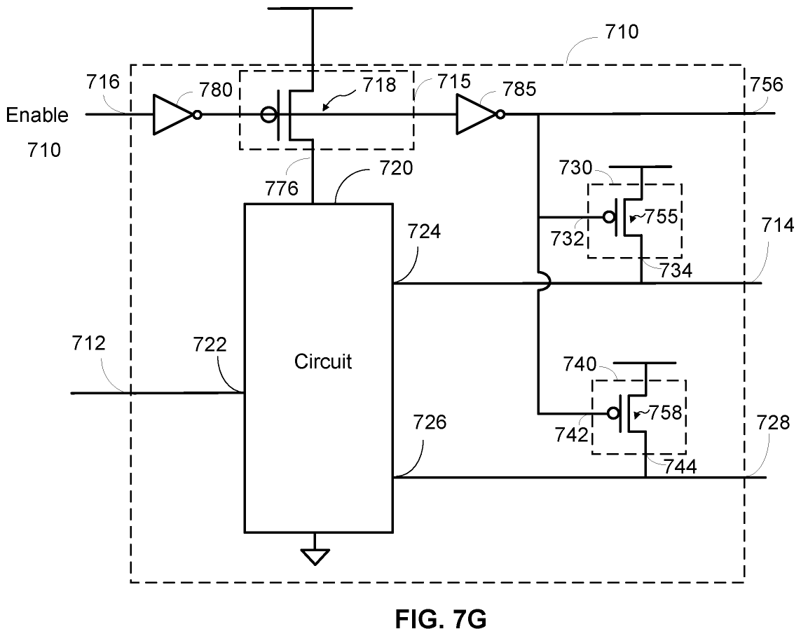

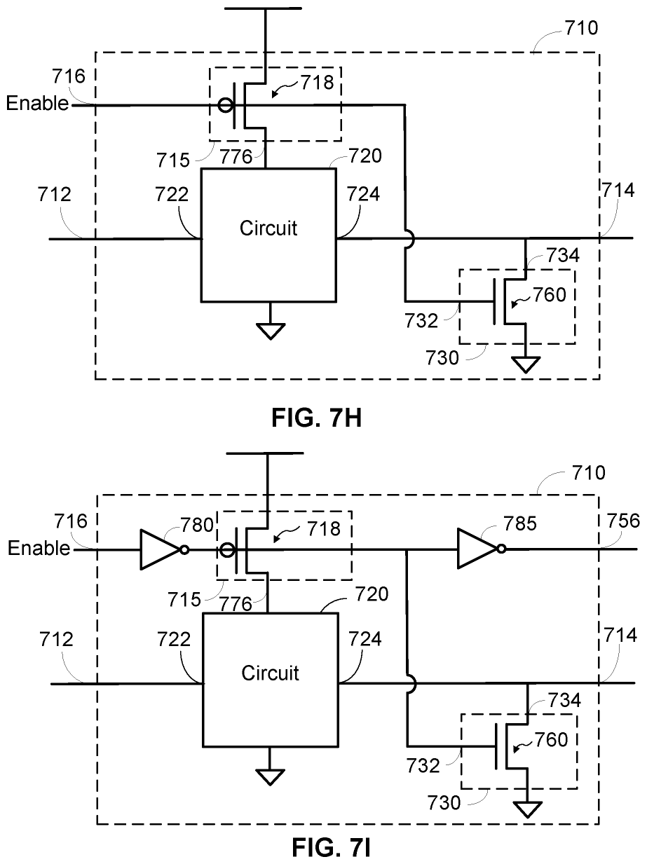

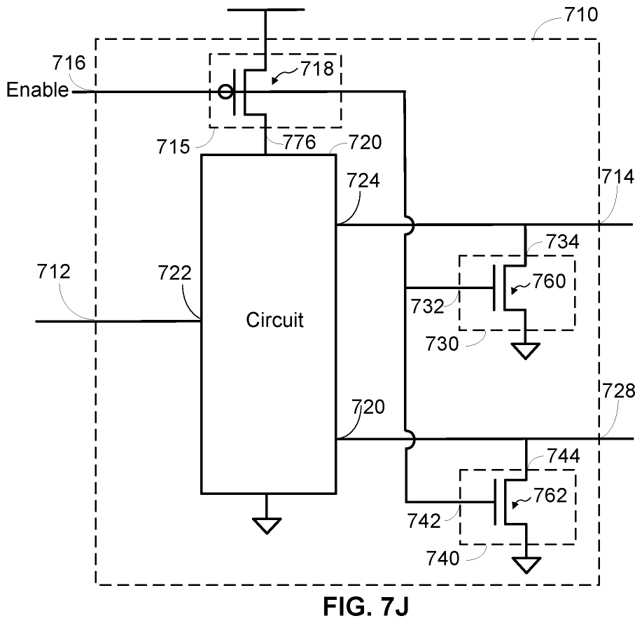

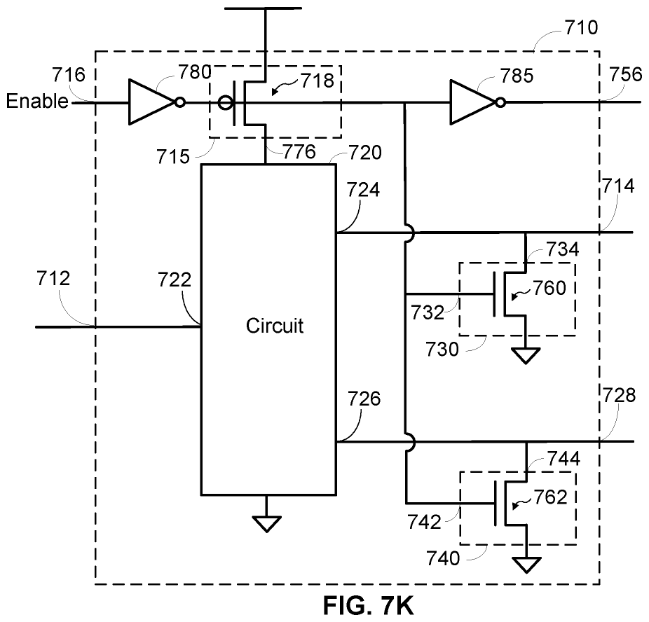

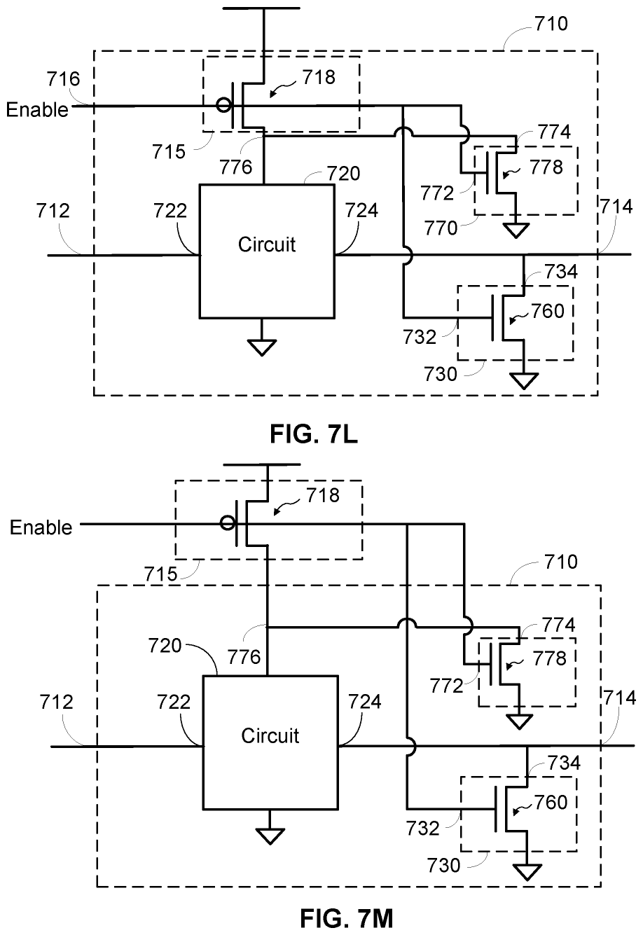

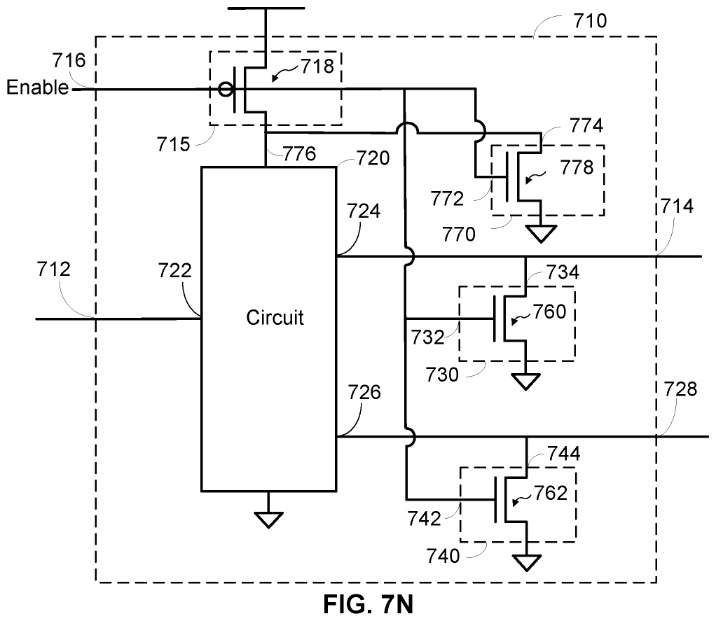

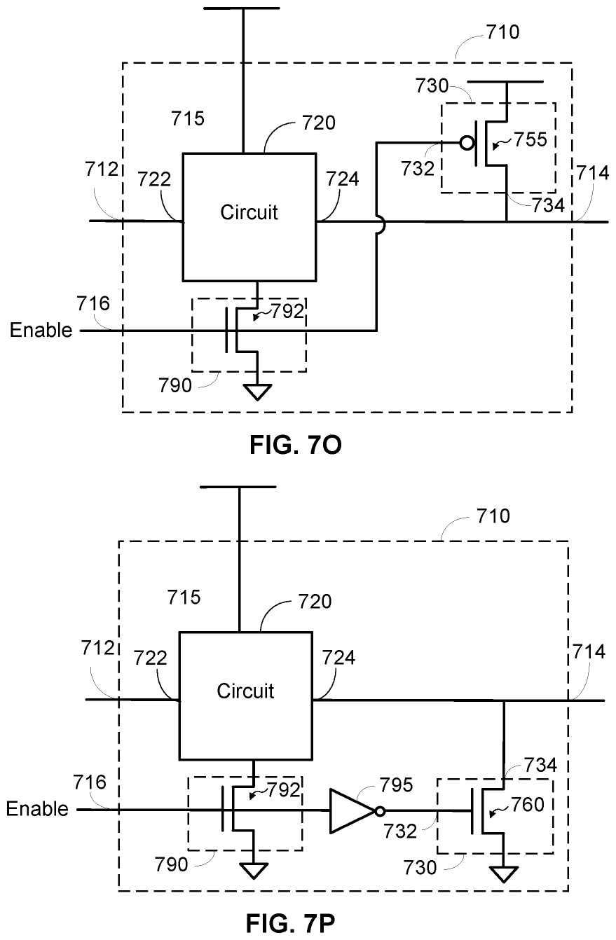

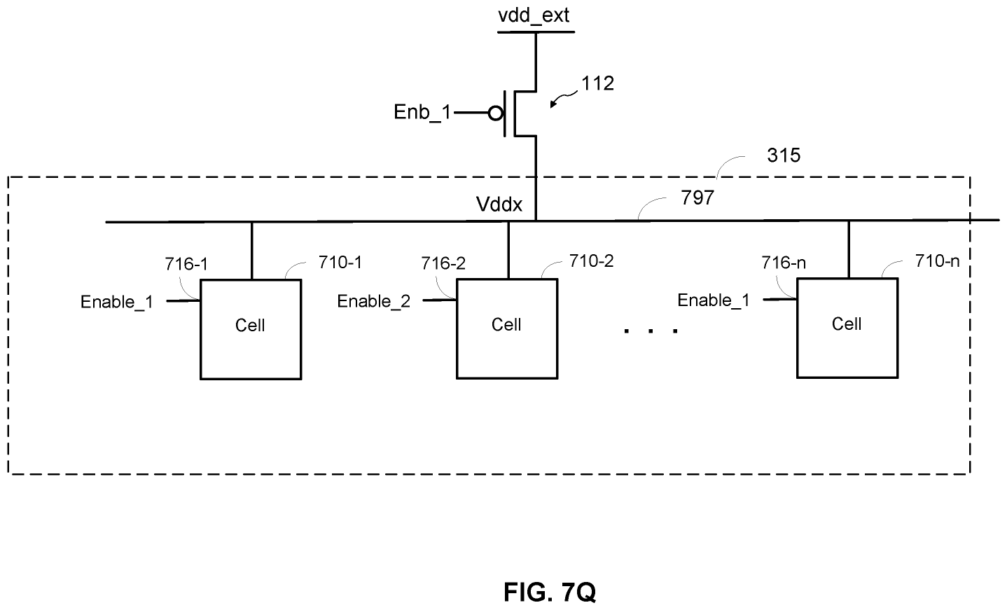

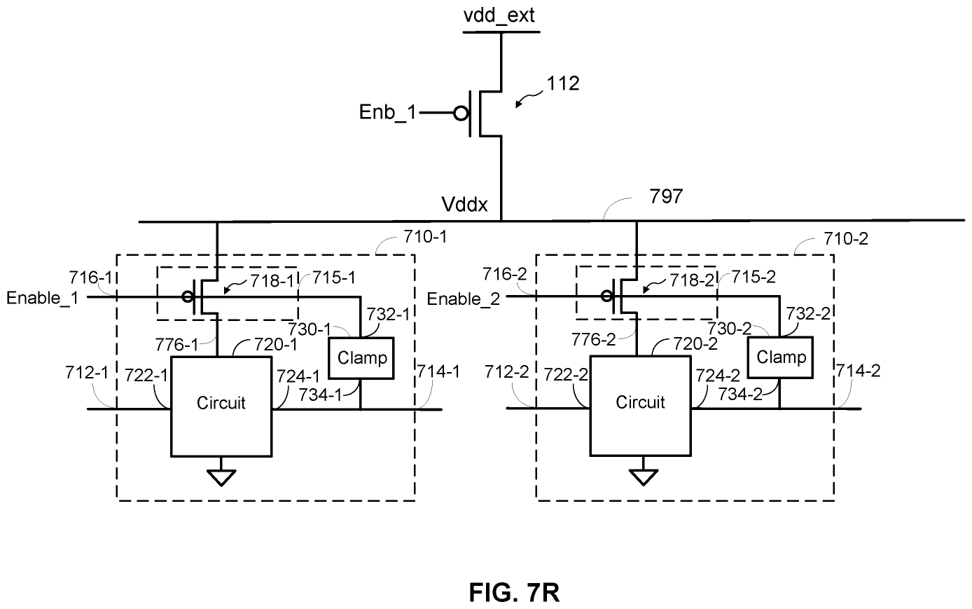

FIG. 7A shows an example of a cell 710 including a circuit 720, a switch 715, and a clamp 730 according to certain aspects. In this example, the switch 715 and the clamp 730 are integrated in the cell 710. The switch 715 is used for selectively power gating the circuit 720. In this regard, the switch 715 may also be referred to as a power-gating switch. Because the switch 715 and the clamp 730 are integrated in the cell 710, a switch and isolation cell do not need to be separately laid out to provide fine power gating for the cell 710 in this example.

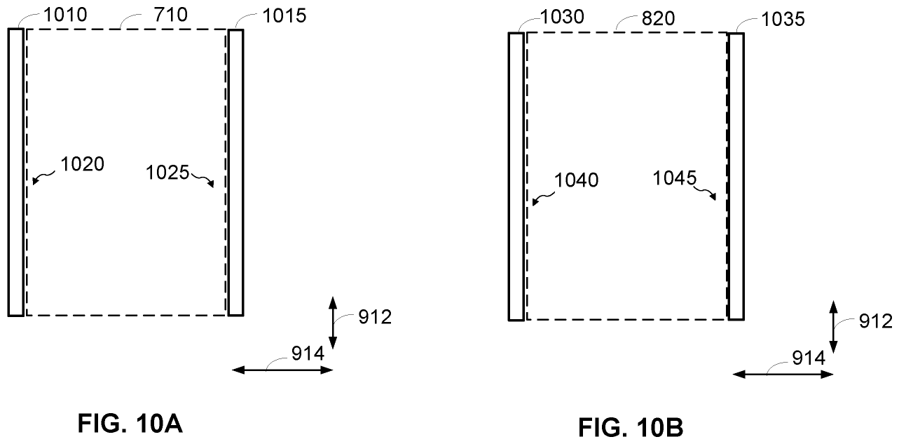

In certain aspects, the cell 710 is defined in a standard cell library that specifies the layout of transistors in the cell 710. The transistors are arranged to provide the circuit 720, the switch 715, and the clamp 730 according to various aspects of the present disclosure. The cell 710 may be used as a building block for an integrated circuit (e.g., circuit 315, 320, 325, or 130) on the chip in which one or more instances of the cell 710 (as defined by the standard cell library) are placed on the chip and coupled to one another and/or other cells in the integrated circuit through metal routing formed from one or more metal layers (e.g., metal M0, metal M1, etc.). In certain aspects, the boundary of the cell 710 may be defined by dummy gates or other physical structures, as discussed further below with reference to FIG. 10A.

The circuit 720 has an input 722 coupled to an input 712 of the cell 710, and an output 724 coupled to an output 714 of the cell 710. The circuit 720 may include a logic gate (e.g., an inverter, a NAND gate, a NOR gate, etc.), one or more flip-flops, a multiplexer, a demultiplexer, a buffer, and/or another circuit (e.g., a circuit configured to perform a basic function). Although one input 722 is shown in FIG. 7, it is to be appreciated that the circuit 720 may include more than one input and/or more than one output. The circuit 720 may also be coupled to ground to provide a ground connection for devices (e.g., transistors) in the circuit 720.

The switch 715 is coupled to the circuit 720 to selectively power gate the circuit 720. The switch 715 may be coupled between a voltage supply rail and the circuit 720. In this example, the switch 715 may also be referred to as a head switch since the switch 715 is between the supply rail and the circuit 720. FIG. 7A shows a node 776 between the switch 715 and the circuit 720. As discussed further below, another clamp may be coupled to the node 776 is some implementations (e.g., to power collapse the circuit 720). The on/off state of the switch 715 is controlled by an enable signal received via an enable input 716 coupled to the switch 715. For example, the switch 715 may be configured to turn on when the enable signal has a first logic value, and turn off when the enable signal has the second logic value.

In the example shown in FIG. 7A, the switch 715 is implemented with a PFET 718, in which the gate of the PFET 718 is coupled to the enable input 716. The source of the PFET 718 may be coupled to the supply rail, and the drain of the PFET 718 may be coupled to the circuit 720. In this example, the switch 715 is turned off when the enable signal is high (e.g., the enable signal is at a supply voltage), and turned on when the enable signal is low (e.g., the enabled signal is at ground). Thus, the circuit 720 is power gated when the enable signal is high. In this example, the first logic value is low (i.e., logic zero) and the second logic value is high (i.e., logic one). However, it is to be appreciated that the present disclosure is not limited to this example.

The clamp 730 has a first terminal 732 coupled to the enable input 716, and a second terminal 734 coupled to the output 714 of the cell 710. The clamp 730 is configured to clamp the output 714 of the cell 710 to a defined logic state when the enable signal has the second logic value (e.g., high) that turns off the switch 715. Thus, when the circuit 720 is power gated, the clamp 730 clamps the output 714 of the cell 710 to the defined logic state, and therefore performs the function of an isolation cell. In some implementations, the clamp 730 is configured to clamp the output 714 high. In other implementations, the clamp 730 is configured to clamp the output 714 low. The clamp 730 is configured to allow the output 724 of the circuit 720 drive the output 714 of the cell 710 when the enable signal has the first logic value (e.g., low) that turns on the switch 715. For the example where the switch 715 is implemented with the PFET 718, the clamp 730 is configured to clamp the output 714 of the cell 710 when the enable signal is high, and allow the output 724 of the circuit 720 to drive the output 714 of the cell 710 when the enable signal is low.

FIG. 7B shows an example in which the circuit 720 includes a logic gate 738. The logic gate 738 may include an inverter, a NAND gate, a NOR gate, an AND gate, an OR gate, or any combination thereof. In certain aspects, the logic gate may include combinational logic that includes two or more logic gates that are combined to perform a logic function.

As discussed above, the circuit 720 may have more than one output in some implementations. In this regard, FIG. 7C shows an example in which the circuit 720 has a second output 726 coupled to a second output 728 of the cell 710. In this example, the cell 710 includes a second clamp 740 coupled to the second output 728. Thus, in this example, the cell 710 includes clamps 730 and 740 for the outputs 714 and 728, respectively. In the example, the circuit 720 may include a demultiplexer, combinational logic with two or more outputs, and the like.

The second clamp 740 may be a separate instance of the first clamp 730. The second clamp 740 has a first terminal 742 coupled to the enable input 716, and a second terminal 744 coupled to the second output 728 of the cell 710. The second clamp 740 is configured to clamp the second output 728 of the cell 710 to a defined logic state when the enable signal has the second logic value (e.g., high) that turns off the switch 715. The defined logic state may be high or low. The clamps 730 and 740 may clamp the respective outputs 714 and 728 to the same defined logic state or different logic states. The second clamp 740 is configured to allow the second output 726 of the circuit 720 to drive the second output 728 of the cell 710 when the enable signal turns on the switch 715 (e.g., the enable signal is low for the example where the switch 715 includes the PFET 718).

FIG. 7D shows an example in which the clamp 730 includes a PFET 755 according to certain aspects. In this example, the gate of the PFET 755 is coupled to the first terminal 732 of the clamp 730. The source of the PFET 755 may be coupled to the supply rail, and the drain of the PFET 755 may be coupled to the output 714 of the cell 710. In this example, the cell 710 also includes an inverter 752 coupled between the enable input 716 of the cell 710 and the first terminal 732 of the clamp 730 (and hence the gate of the PFET 755). More particularly, the input of the inverter 752 is coupled to the enable input 716 and the output of the inverter 752 is coupled to the first terminal 732.

In this example, when the enable signal is high, the switch 715 is turned off (i.e., the circuit 720 is power gated). The inverter 752 inverts the enable signal, and outputs a low logic state to the gate of the PFET 755 in the clamp 730. As a result, the PFET 755 is turned on, causing the PFET 755 to the clamp the output 714 of the cell 710 high (e.g., to the supply voltage on the supply rail). Thus, in this example, the clamp 730 clamps the output high when the circuit 720 is power gated.

In this example, when the enable signal is low, the switch 715 is turned on. The inverter 752 inverts the enable signal, and outputs a high logic state to the gate of the PFET 755 in the clamp 730. As a result, the PFET 755 is turned off, allowing the output 724 of the circuit 720 to drive the output 714 of the cell 710.

FIG. 7E shows an example in which the cell 710 includes a first buffer 780 and a second buffer 785 in the enable signal path. In the example in FIG. 7E, each of the buffers 780 and 785 is implemented with a respective inverter. However, it is to be appreciated that the present disclosure is not limited to this example. In this example, the first buffer 780 is coupled between the enable input 716 and the switch 715 (e.g., the gate of the PFET 718). More particularly, the input of the first buffer 780 is coupled to the enable input 716 and the output of the first buffer 780 is coupled to the switch 715 (e.g., the gate of the PFET 718). The second buffer 785 is coupled between the switch (e.g., gate of the PFET 718) and an enable output 756 of the cell 710. More particularly, the input of the second buffer 785 is coupled to the switch 715 and the output of the second buffer 785 is coupled to the enable output 756.

In this example, the buffers 780 and 785 are coupled in series (i.e., chain) in the enable path between the enable input 716 and the enable output 756. This allows the enable path in the cell 710 to be daisy chained with the enable paths of other cells (not shown). For example, the enable output 756 may be coupled to the enable input of another cell (not shown).

In this example, the output of the second buffer 785 is also coupled to the gate of the PFET 755 in the clamp 730. Since the second buffer 785 is implemented with an inverter in the example shown in FIG. 7D, the second buffer 785 inverts the enable signal between the switch 715 and the PFET 755, and therefore performs the inverting function of the inverter 752 shown in FIG. 7D.

Since the first buffer 780 is implemented with an inverter in the example shown in FIG. 7E, the switch 715 is turned on when the enable signal at the enable input 716 is high, and turned off when the enable signal at the enable input 716 is low. Also, the clamp 730 clamps the output 714 of the cell 710 high when the enable signal at the enable input 716 is low, and allows the circuit 720 to drive the output 714 of the cell when the enable signal at the enable input 716 is high.

FIG. 7F shows an example in which the cell 710 shown in FIG. 7D includes the second clamp 740. In this example, the second clamp 740 includes a PFET 758 where the gate of the PFET 758 is coupled to the first terminal 742 of the second clamp 740, the source of the PFET 758 may be coupled to the supply rail, and the drain of the PFET 758 may be coupled to the second output 728 of the cell 710. The first terminal 742 of the second clamp 740 is coupled to the output of the inverter 752 discussed above. In this example, the second clamp 740 clamps the second output 728 high when the switch 715 is turned off.

FIG. 7G shows an example in which the cell 710 shown in FIG. 7E includes the second clamp 740. In this example, the first terminal 742 of the second clamp 740 is coupled to the output of the buffer 785, and the second clamp 740 includes the PFET 758 discussed above with reference to FIG. 7F.

FIG. 7H shows an example in which the clamp 730 includes an NFET 760 according to certain aspects. In this example, the gate of the NFET 760 is coupled to the first terminal 732 of the clamp 730. The drain of the NFET 760 may be coupled to the output 714 of the cell 710, and the source of the NFET 760 may be coupled to ground. In this example, the gate of the NFET 760 is coupled to the enable input 716 of the cell 710 to receive the enable signal.

In this example, when the enable signal is high, the switch 715 is turned off (i.e., the circuit 720 is power gated) and the NFET 760 is turned on. As a result, the NFET 760 clamps the output 714 of the cell 710 low (e.g., to ground). Thus, in this example, the clamp 730 clamps the output 714 low when the circuit 720 is power gated.

In this example, when the enable signal is low, the switch 715 is turned on, and the NFET 760 is turned off, allowing the output 724 of the circuit 720 to drive the output 714 of the cell 710.

FIG. 7I shows an example in which the cell 710 includes the first buffer 780 and the second buffer 785 in the enable signal path discussed above. In this example, the gate of the PFET 718 and the gate of the NFET 760 are both coupled between the output of the first buffer 780 and the input of the second buffer 785.

FIG. 7J shows an example in which the cell 710 shown in FIG. 7H includes the second clamp 740. In this example, the second clamp 740 includes an NFET 762 where the gate of the NFET 762 is coupled to the first terminal 742 of the second clamp 740, the source of the NFET 762 may be coupled to the ground, and the drain of the NFET 762 may be coupled to the second output 728 of the cell 710. In this example, the second clamp 740 clamps the second output 728 low when the switch 715 is turned on. For the example where the switch 715 includes the PFET 718, the gate of the NFET 762 may be coupled to the gate of the PFET 718, as shown in the example in FIG. 7J. However, it is to be appreciated that the present disclosure is not limited to this example.

FIG. 7K shows an example in which the cell 710 shown in FIG. 7I includes the second clamp 740. In this example, the first terminal 742 of the second clamp 740 is coupled between the output of the buffer 780 and the input of the buffer 785, and the second clamp 740 includes the NFET 762 discussed above with reference to FIG. 7J.

FIG. 7L shows an example in which the cell 710 includes a second clamp 770 according to certain aspects. In this example, the second clamp 770 has a first terminal 772 coupled to the enable input 716, and a second terminal 774 coupled to the node 776 between the switch 715 (e.g., drain of the PFET 718) and the circuit 720.

In this example, when the enable signal has the second logic value (e.g., high) that turns off the switch 715 (i.e., power gates the circuit 720), the second clamp 770 clamps the node 776 between the switch 715 and the circuit 720 low (e.g., to ground), which power collapses the circuit 720.

In the example in FIG. 7L, the second clamp 770 includes an NFET 778. The gate of the NFET 778 is coupled to the first terminal 772, the drain of the NFET 778 is coupled to the second terminal 774, and the source of the NFET 778 is coupled to ground. In this example, the NFET 778 turns on and clamps the node 776 between the switch 715 and the circuit 720 low (e.g., to ground) when the enable signal is high. The NFET 778 turns off when the enable signal is low.

In the example in FIG. 7L, the cell 710 also includes the clamp 730 discussed above with reference to FIG. 7E. However, it is to be appreciated that the clamp 730 may be omitted from FIG. 7G in some implementations. For example, clamping the node 776 to ground may cause the output 724 of the circuit 720 to be low when the circuit 720 is power gated. In this example, the second clamp 770 may simply be referred to as the clamp.

FIG. 7M shows an example in which the switch 715 is outside the cell 710 (i.e., not included in the cell 710). In the example in FIG. 7M, the cell 710 includes the clamps 730 and 770 discussed above with reference to FIGS. 7L and 7H. In this example, the first terminal 732 of the clamp 730 is coupled to the gate of the PFET 718, and the first terminal 772 of the second clamp 770 is coupled to the gate of the PFET 718. However, it is to be appreciated that the present disclosure is not limited to this example. For example, one of the clamps 730 and 770 may be omitted from FIG. 7L. For example, in some implementations, the clamp 730 may be omitted from FIG. 7L. In other implementations, the second clamp 770 may be omitted from FIG. 7L.

FIG. 7N shows an example in which the cell 710 shown in FIG. 7L includes the second clamp 740. In this example, the second clamp 740 includes the NFET 762 discussed above where the gate of the NFET 762 is coupled to the first terminal 742 of the second clamp 740, the source of the NFET 762 may be coupled to the ground, and the drain of the NFET 762 may be coupled to the second output 728 of the cell 710.

It is to be appreciated that the cell 710 is not limited to the switch 715 to implement fine power gating. In this regard, FIG. 7O shows an example of the cell 710 shown in FIG. 7D in which the switch 715 is replaced with a switch 790 according to certain aspects. The switch 790 is coupled between the circuit 720 and ground. In this example, the switch 790 may also be referred to as a foot switch since the switch 790 is coupled between the circuit 720 and ground. The on/off state of the switch 790 is controlled by the enable signal received via the enable input 716.

In the example shown in FIG. 7O, the switch 790 is implemented with an NFET 792 in which the gate of the NFET 792 is coupled to the enable input 716. The drain of the NFET 792 is coupled to the circuit 720 and the source of the NFET 792 is coupled to the ground. In this example, the switch 790 turns on when the enable signal is high, and turns off and gates the power to the circuit 720 when the enable signal is low.

In this example, the clamp 730 includes the PFET 755 in which the gate of the PFET 755 is coupled to the enable input 716, the source of the PFET 755 is coupled to the supply rail, and the drain of the PFET 755 is coupled to the output 714. In this example, the PFET 775 turns on when the switch 790 is turned off and clamps the output 714 of the cell 710 high. The PFET 755 turns off when the switch 790 is turned on.

FIG. 7P shows an example in which the clamp 730 includes the NFET 760 discussed above with reference to FIG. 7H. The drain of the NFET 760 is coupled to the output 714 and the source of the NFET 760 is coupled to ground. In this example, the cell 710 includes an inverter 795 coupled between the enable input 716 and the gate of the NFET 760 of the clamp 730. The input of the inverter 795 is coupled to the enable input 716 and the output of the inverter 795 is coupled to the gate of the NFET 760. In this example, the inverter 795 turns on the NFET 760 when the switch 790 is turned off to clamp the output 714 of the cell 710 low. The inverter 795 turns off the NFET 760 when the switch 790 is turned on.

It is to be appreciated that the circuit 720 shown in FIGS. 70 and 7P may include two or more inputs and/or two or more outputs. For the example where the circuit 720 includes two or more outputs, the cell 710 may include a separate instance of the clamp 730 for each of the outputs.

In certain aspects, one or more of the circuits 315, 320, and 325 shown in FIG. 3A or FIG. 3B may each include multiple instances of the cell 710. For example, FIG. 7Q shows an example in which the circuit 315 includes cells 710-1 to 710-n. Each of the cells 710-1 to 710-n may be a separate instance of the cell 710 according to any of the exemplary implementations shown in FIGS. 7A to 7P. Two or more of the cells 710-1 and 710-n may be separate instances of the same implementation of the cell 710 shown in any one of the FIGS. 7A to 7P. In another example, two or more of the cells 710-1 and 710-n may be instances of different implementations of the cell 710 shown in FIGS. 7A to 7P. The inputs and outputs of the cells 710-1 to 710-n are not explicitly shown in FIG. 7Q for case of illustration.

In this example, the first switch 112 is coupled between a first supply rail with supply voltage vdd_ext and a second rail 797 in the first circuit 315. The first supply rail may be coupled to the power source 150 shown in FIG. 3A. In this example, the first switch 112 receives enable signal Enb_1 to control power gating of the circuit 315. The supply rail in the discussion of FIGS. 7A to 7P may refer to the first rail and/or the second rail 797.

In some implementation, fine power gating of each of the cells 710-1 to 710-n may be independently controlled by a respective one of the enable signals Enable_1 to Enable_n. In some implementations two or more of the cells 710-1 to 710-n may receive the same enable signal and may be power gated together while other ones of the cells 710-1 to 710-n receive separate enable signals. For example, FIG. 7R shows example where each of cells 710-1 and 710-2 is a separate instance of the exemplary implementation shown in FIG. 7A. In this example, in each of the cells 710-1 and 710-2, the respective switch 715-1 and 715-2 is coupled between the second rail 797 and the respective circuit 720-1 and 720-2, and the on/off state of the respective switch 715-1 and 715-n is controlled by the respective one of the enable signals Enable_1 and Enable_2. In this example, each of the clamps 730-1 and 730-2 may clamp the respective output high or low, and may be implemented with any of the implementations of the clamp 730 shown in FIGS. 7D to 7P. The clamps 730-1 and 730 may be separate instances of the same implementation of the clamp 730 shown in any one of FIGS. 7D to 7P, or may be instances of different implementations of the clamp 730 shown in FIGS. 7D to 7P. It is to be appreciated that the present disclosure is not limited to the example shown in FIG. 7R.

Thus, in this example, the first switch 112 and the switches integrated in the cells 710-1 to 710-n provide two levels of power gating. The first switch 112 provides power gating for the circuit 315, and the switches integrated in the cells 710-1 to 710-n provide independent power gating of the cells 710-1 to 710-n within the circuit 315.

It is to be appreciated that the present disclosure is not limited to the example shown in FIG. 7Q. For example, in some implementations, the switch 332 shown in FIG. 3B may be used in place of the first switch 112 to power gate the circuit 315. Further, it is to be appreciated that the circuit 315 may include one or more additional cells in addition to the cells 710-1 to 710-n.

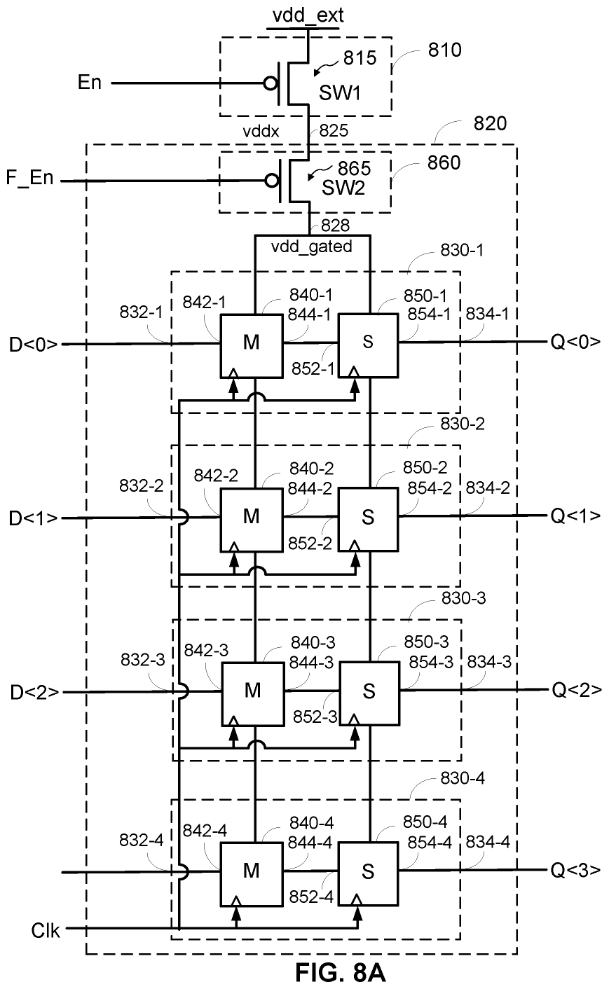

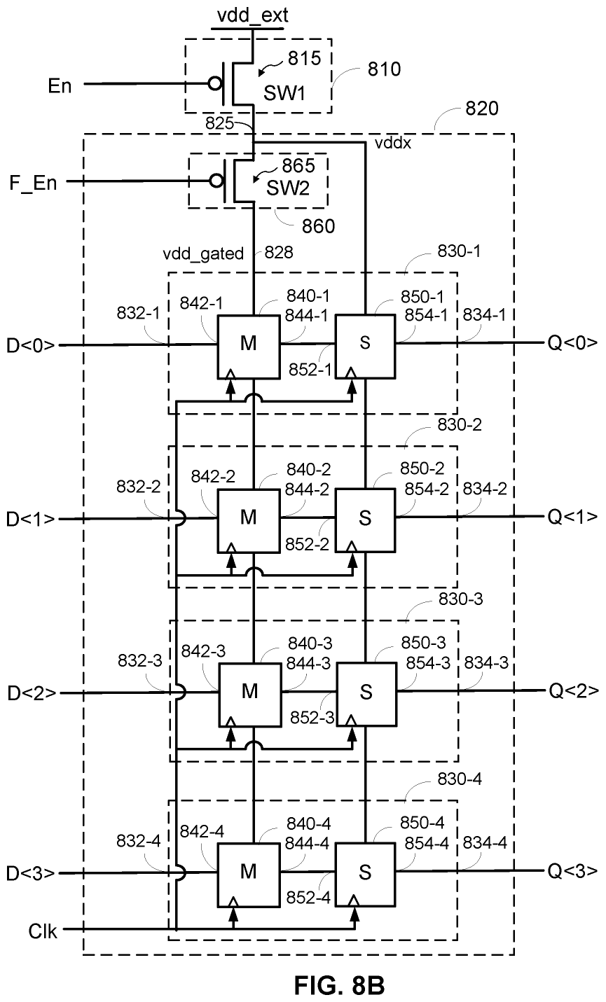

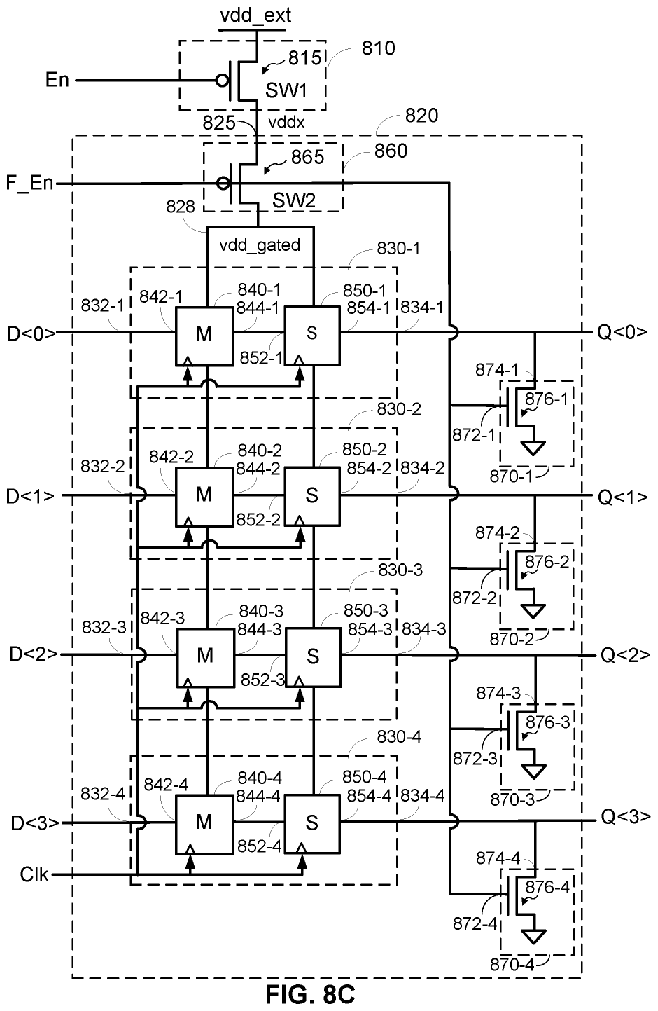

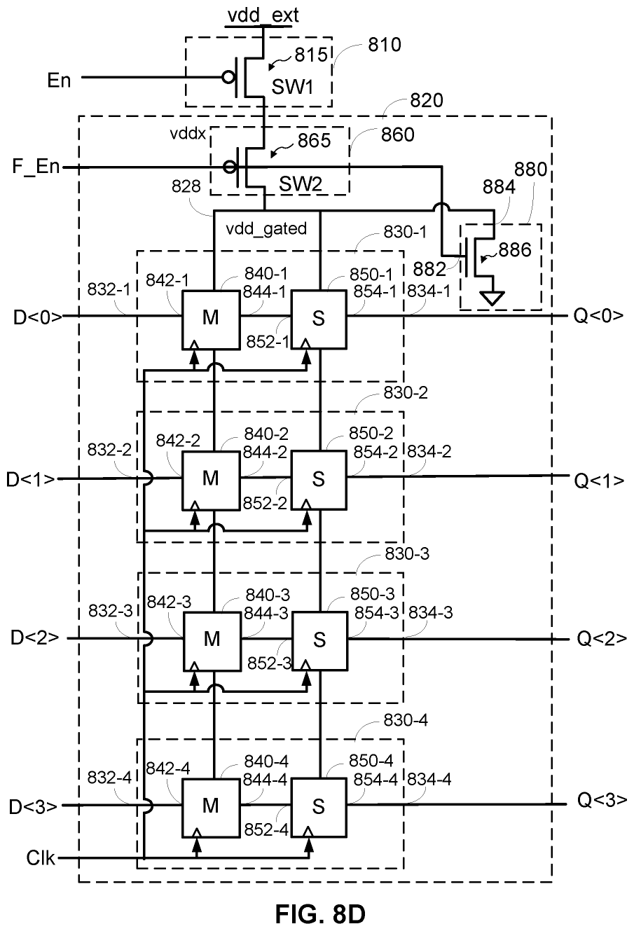

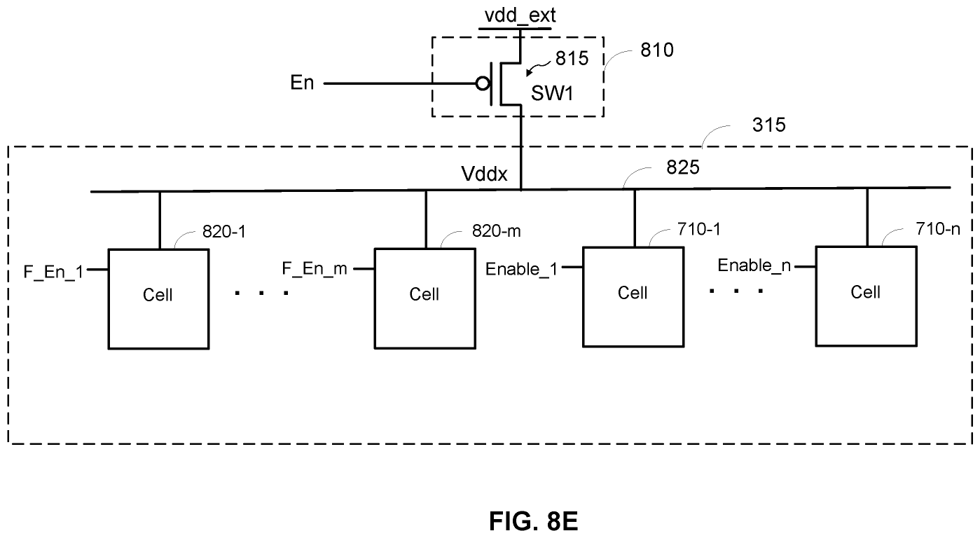

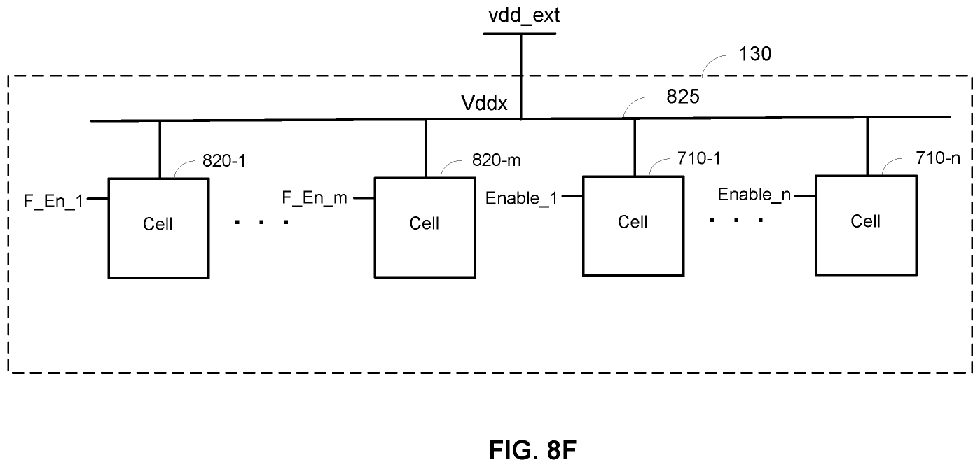

FIG. 8A shows an example of a cell 820 including multiple flip-flops 830-1 to 830-4 according to certain aspects. The cell 820 may also include a switch 860. Although four flip-flops 830-1 to 830-4 are shown in the example in FIG. 8A, it is to be appreciated that the cell 820 may include any number of flip-flops 830-1 to 830-4. In this example, the flip-flops 830-1 to 830-4 are configured to receive a clock signal Clk and respective data bits D<0> to D<3> in parallel, latch the data bits D<0> to D<3> on an edge of the clock signal Clk (e.g., rising edge or falling edge), and output the latches data bits Q<0> to Q<3>. In this example, the flip-flops 830-1 to 830-4 may also be referred to as a flip-flop tray.

In certain aspects, the cell 820 is defined in a standard cell library that specifies the layout of transistors in the cell 820. The transistors are arranged to provide the flip-flops 830-1 to 830-4 and the switch 860 according to various aspects of the present disclosure. The cell 820 may be used as a building block for an integrated circuit (e.g., circuit 315, 320, 325, or 130) on the chip in which one or more instances of the cell 820 (as defined by the standard cell library) are placed on the chip and coupled to one another and/or other cells in the integrated circuit through metal routing formed from one or more metal layers (e.g., metal M0, metal M1, etc.). In certain aspects, the boundary of the cell 820 may be defined by dummy gates or other physical structures, as discussed further below with reference to FIG. 10B.

In this example, each of the flip-flops 830-1 to 830-4 has a respective input 832-1 to 832-4 configured to receive the respective data bit D<0> to D<3>, and a respective output 834-1 to 834-4 configured to output the respective latched data bit Q<0> to Q<3>. In the example in FIG. 8A, each of the flip-flops 830-1 to 830-4 may be implemented with a master-slave architecture including a respective master latch 840-1 to 840-4 and a respective slave latch 850-1 to 850-4 coupled in series. However, it is to be appreciated that the present disclosure is not limited to this example.

In the example in FIG. 8A, the master latch 840-1 to 840-4 in each flip-flop 830-1 to 830-4 has an input 842-1 to 842-4 configured to receive the respective data bit, and an output 844-1 to 844-4. The slave latch 850-1 to 850-4 in each flip-flop 830-1 to 830-4 has an input 852-1 to 852-4 coupled to the output 844-1 to 844-4 of the respective master latch 840-1 to 840-4, and an output 854-1 to 854-4 configured to output the respective latched data bit. The clock signal Clk may be input to clock inputs (represented by triangles) of the master latches 840-1 to 840-4 and the slave latches 850-1 to 850-4 to clock the master latches 840-1 to 840-4 and the slave latches 850-1 to 850-4.

In certain aspects, the master latches 840-1 to 840-4 may be triggered by a rising edge of the clock signal Clk and the slave latches 850-1 to 850-4 may be triggered by a falling edge of the clock signal Clk, or vice versa. In one example, the master latches 840-1 to 840-4 may latch the data bits D<0> to D<3> at the respective inputs 842-1 to 842-4 on the rising edge of the clock signal Clk, and output the latched data bits at the respective outputs 844-1 to 844-4. The slave latches 850-1 to 850-4 may receive the latched data bits from the respective master latches 840-1 to 840-4 at the respective inputs 852-1 to 852-4, latch the data bits from the respective master latches 840-1 to 840-4 on the falling edge of the clock signal Clk, and output the latched data bits Q<0> to Q<3> at the respective outputs 854-1 to 854-4. It is to be appreciated that the master latches 840-1 to 840-4 and the slave latches 850-1 to 850-4 are not limited to this example.

In the example in FIG. 8A, the cell 820 may be power gated by a switch 810 coupled between an external supply rail and a rail 825. The external supply rail has a supply voltage vdd_ext, which may be provided by a power source (e.g., power source 150). The external supply rail may also be referred to as a first supply rail and the rail 825 may also be referred to as a second supply rail.

In the example in FIG. 8A, the switch 810 is implemented with a respective PFET 815. In this example, the switch 810 turns on when the enable signal En is low, and turns off when the enable signal En is high. However, it is to be appreciated that the present disclosure is not limited to this example. In some implementations, the switch 810 may control power gating for the cell 820 and one or more additional cells (not shown) coupled to the rail 825.

In this example, the switch 860 in the cell 820 is coupled between the rail 825 and a node 828 of the cell 820. The node 828 is coupled to the flip-flops 830-1 to 830-4 to provide supply voltage vdd_gated to the flip-flops 830-1 to 830-4. For the example where each flip-flop 830-1 to 830-4 includes the respective master latch 840-1 to 840-4 and the respective slave latch 850-1 to 850-4, the node 828 is coupled to the master latches 840-1 to 840-4 and the slave latches 850-1 to 850-4.

In this example, the switch 860 in the cell 820 facilitates fine power gating of the flip-flops 830-1 to 830-4. The switch 860 receive an enable signal F_En, and selectively power gates the flip-flops 830-1 to 830-4 based on the enable signal F_En. For example, the switch 860 may turn on when the enable signal F_En has a first logic value (e.g., low), and turn off (i.e., power gate the flip-flops 830-1 to 830-4) when the enable signal F_En has a second logic value (e.g., high). In the example in FIG. 8A, the switch 860 is implemented with a PFET 865, in which the gate of the PFET 865 is configured to receive the enable signal F_En. In this example, the source of the PFET 865 may be coupled to the rail 825, and the drain of the PFET 865 may be coupled to the node 828. However, it is to be appreciated that the present disclosure is not limited to this example.

Thus, the switch 810 and the switch 860 provide two levels of power gating. The switch 810 provides power gating for the cells coupled to the rail 825 including the cell 820, and the switch 860 provides individually power gating for the cell 820.

FIG. 8B shows an example in which the master latches 840-1 to 840-4 are coupled to the node 828, and the slave latches 850-1 to 850-4 are coupled to rail 825. In this example, the switch 860 controls fine power gating of the master latches 840-1 to 840-4. When the switch 860 is turned off by the enable signal F_En, the master latches 840-1 to 840-4 are power gated. In this case, the slave latches 850-1 to 850-4 may receive power from rail 825. In certain aspects, the clock signal Clk may also be gated when the master latches 840-1 to 840-4 are power gated. In this case, the slave latches 850-1 to 850-4 retain their current output logic states. In other words, the outputs 854-1 to 854-4 of the slave latches 850-1 to 850-4 may be fixed at the logic states retained by the slave latches 850-1 to 850-4.

FIG. 8C shows an example in which the cell 820 includes clamps 870-1 to 870-4 according to certain aspects. Each of the clamps 870-1 to 870-4 has a respective first terminal 872-1 to 872-4 configured to receive the enable signal F_En, and a respective second terminal 874-1 to 874-4 coupled to a respective one of the outputs 834-1 to 834-4 of the flip-flops 830-1 to 830-4. Each of the clamps 870-1 to 870-4 is configured to clamp the respective one of the outputs 834-1 to 834-4 of the flip-flops 830-1 to 830-4 to a defined logic state when the enable signal F_En has the second logic value (e.g., high) that turns off the switch 860. Thus, when the flip-flops 830-1 to 830-4 are power gated, the clamps 870-1 to 870-4 clamp the outputs 834-1 to 834-4 to the defined logic state. In some implementations, the defined logic state is low. In other implementations, the defined logic state is high.

In the example in FIG. 8C, each of the clamps 870-1 to 870-4 includes a respective NFET 876-1 to 876-4, in which the gate of the NFET 876-1 to 876-4 receives the enable signal F_En, the drain of the NFET 876-1 to 876-4 is coupled to the respective second terminal 874-1 to 874-4, and the source of the NFET 876-1 to 876-4 is coupled to ground. For the example where the switch 860 includes the PFET 865, the gates of the NFETs 876-1 to 876-4 may be coupled to the gate of the PFET 865. In this example, the PFET 865 turns on and the NFETs 876-1 to 876-4 turn off when the enable signal F_En is low. The PFET 865 turns off (i.e., power gates the flip-flops 830-1 to 830-4) and the NFETs 876-1 to 876-n turn on (i.e., clamp the outputs 834-1 to 834-4 low) when the enable signal F_En is high. However, it is to be appreciated that the present disclosure is not limited to this example.

FIG. 8D shows an example in which the cell 820 includes a clamp 880 according to certain aspects. The clamp 880 has a first terminal 882 configured to receive the enable signal F_En, and a second terminal 884 coupled to the node 828. The clamp 880 is configured to clamp the node 828 low when the enable signal F_En has the second logic value (e.g., high) that turns off the switch 860. Thus, when the flip-flops 830-1 to 830-4 are power gated, the clamp 880 clamps the node 828 low (e.g., to ground), which power collapses the node 828.

In the example in FIG. 8D, the clamp 880 includes an NFET 886, in which the gate of the NFET 886 receives the enable signal F_En. The drain of the NFET 886 is coupled to the node 828, and the source of the NFET 886 is coupled to ground. For the example where the switch 860 includes the PFET 865, the gate of the NFET 886 may be coupled to the gate of the PFET 865. In this example, the PFET 865 turns on and the NFET 876 turns off when the enable signal F_En is low. The PFET 865 turns off (i.e., power gates the flip-flops 830-1 to 830-4) and the NFET 886 turns on (i.e., clamps the node 828 low) when the enable signal F_En is high. However, it is to be appreciated that the present disclosure is not limited to this example.

It is to be appreciated that, in some implementations, the cell 820 may include both the clamps 870-1 to 870-4 shown in FIG. 8C and the clamp 880 shown in FIG. 8D.

In certain aspects, one or more of the circuits 315, 320, and 325 shown in FIG. 3A or FIG. 3B may each include multiple instances of the cell 820. For example, FIG. 8E shows an example in which the circuit 315 includes cells 820-1 to 820-m. Each of the cells 820-2 to 820-m may be a separate instance of the cell 820 according to any of the exemplary implementations shown in FIGS. 8A to 8D. Two or more of the cells 820-1 and 820-m may be separate instances of the same implementation of the cell 820-1 to 820-m shown in any one of the FIGS. 8A to 8D. In another example, two or more of the cells 820-1 and 820-m may be instances of different implementations of the cell 820 shown in FIGS. 8A to 8D. The inputs and outputs of the cells 820-1 to 820-m are not explicitly shown in FIG. 8E for case of illustration.

In this example, the switch 810 is coupled between the first supply rail with supply voltage vdd_ext and the second rail 825. The first supply rail may be coupled to the power source 150 shown in FIG. 3A. In this example, the switch 810 receives enable signal En to control power gating of the circuit 315.

In some implementation, fine power gating of each of the cells 820-1 to 820-m may be independently controlled by a respective one of the enable signals F_En_1 to F_En. In some implementations two or more of the cells 820-1 to 820-m may receive the same enable signal and may be power gated together while other ones of the cells 820-2 to 820-m receive separate enable signals. In each of the cells 820-1 to 820-4, the respective instance of the switch 860 is coupled to the second rail 825.

Thus, in this example, the switch 810 and the switches integrated in the cells 820-1 to 820-m (i.e., respective instances of the switch 860) provide two levels of power gating. The switch 810 provides power gating for the circuit 315, and the switches integrated in the cells 820-1 to 820-m provide independent power gating of the cells 820-1 to 820-m within the circuit 315.

In certain aspects, the circuit 315 also includes the cells 710-1 to 710-n discussed above with reference 7Q, which are multiple instances of the cell 710. In this example, the cells 710-1 to 710-n are coupled to the second rail 825, which corresponds to the second rail 797 in FIG. 7Q.

In certain aspects, the AON circuit 130 may include multiple instances of the cell 820. For example, FIG. 8F shows an example in which the AON circuit 130 includes the cells 820-1 to 820-m discussed above. In this example, the switch 810 is omitted and the second rail 825 is coupled to the first supply rail without power gating between the two rails.

Each of the cells 820-2 to 820-m may be a separate instance of the cell 820 according to any of the exemplary implementations shown in FIGS. 8A to 8D. Two or more of the cells 820-1 and 820-m may be separate instances of the same implementation of the cell 820-1 to 820-m shown in any one of the FIGS. 8A to 8D. In another example, two or more of the cells 820-1 and 820-m may be instances of different implementations of the cell 820 shown in FIGS. 8A to 8D.

Fine power gating of each of the cells 820-1 to 820-m may be independently controlled by the respective one of the enable signals F_En_1 to F_En. In some implementations two or more of the cells 820-1 to 820-m may receive the same enable signal and may be power gated together while other ones of the cells 820-2 to 820-m receive separate enable signals. In each of the cells 820-1 to 820-4, the respective instance of the switch 860 is coupled to the second rail 825.

In certain aspects, the AON circuit 130 also includes the cells 710-1 to 710-n discussed above with reference 7Q, which are multiple instances of the cell 710. In this example, the cells 710-1 to 710-n are coupled to the second rail 825, which corresponds to the second rail 797 in FIG. 7Q.

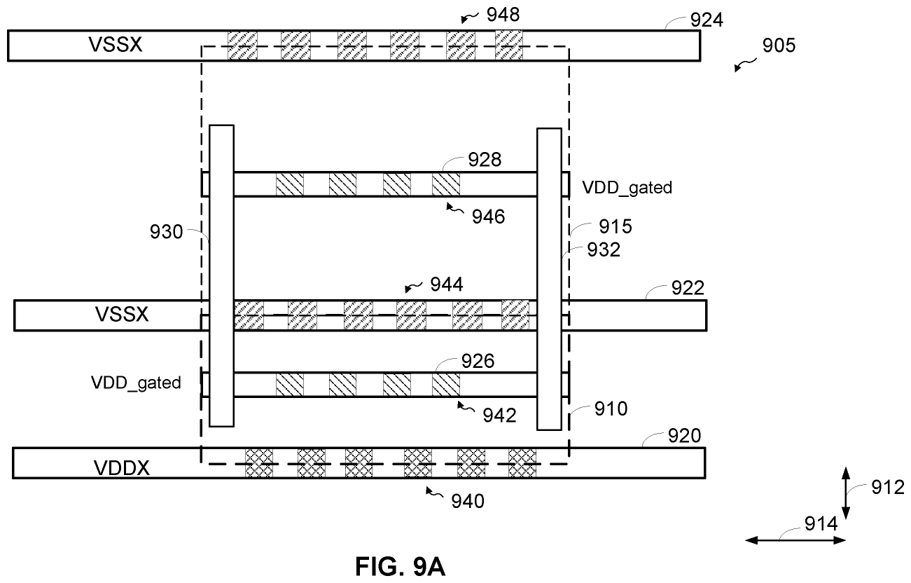

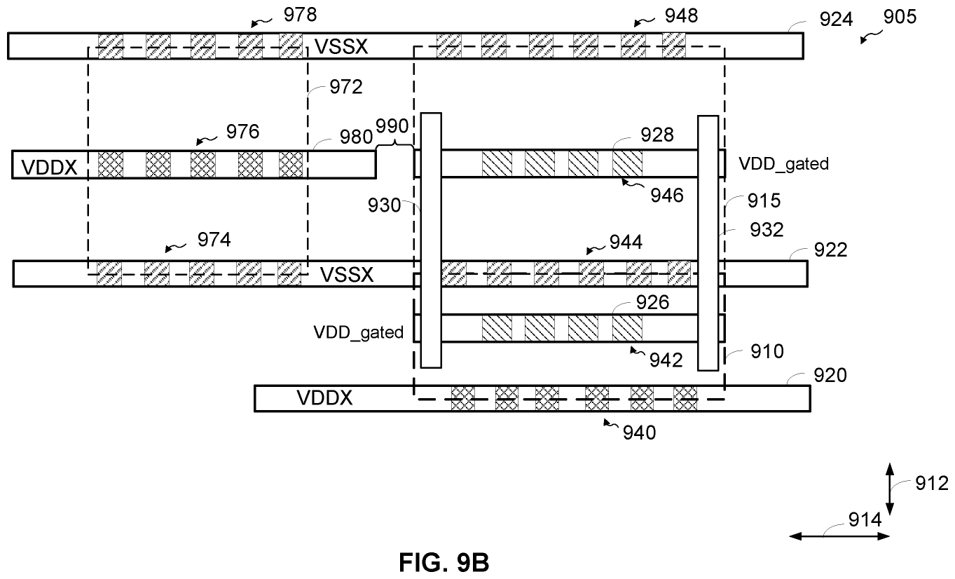

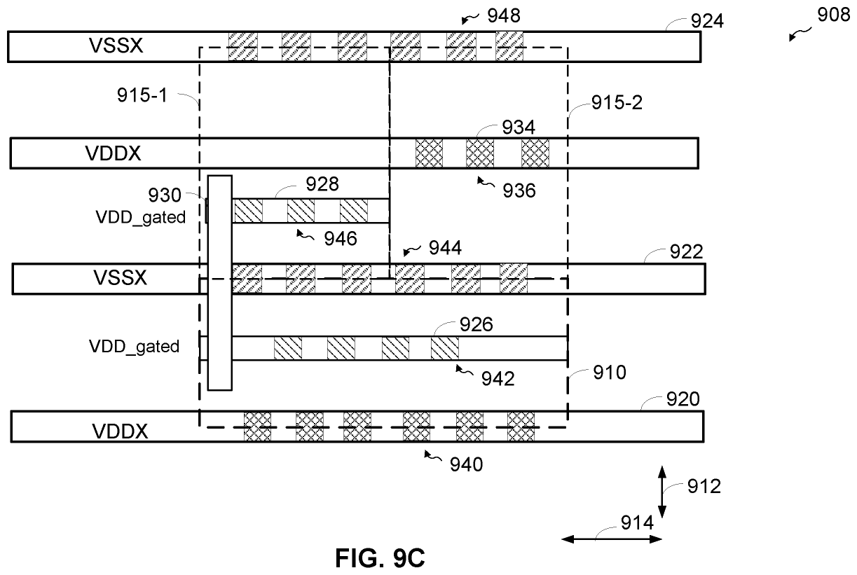

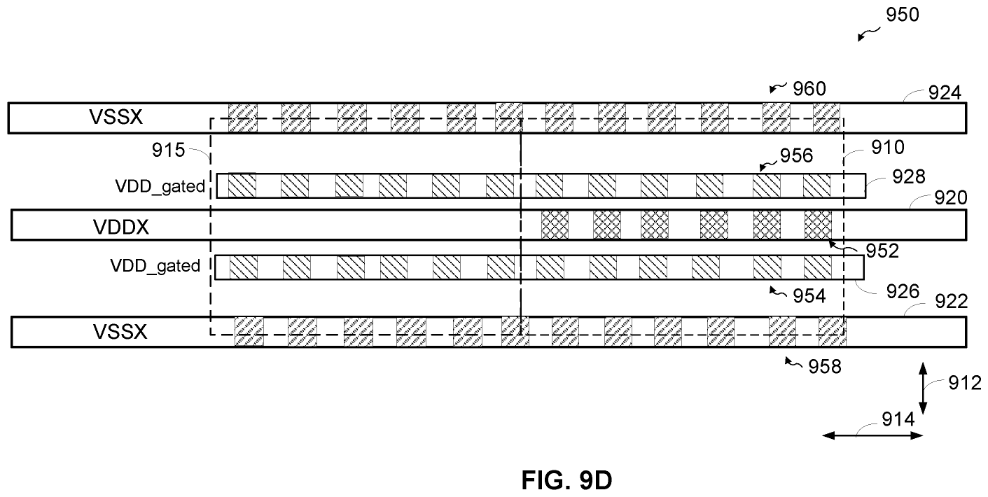

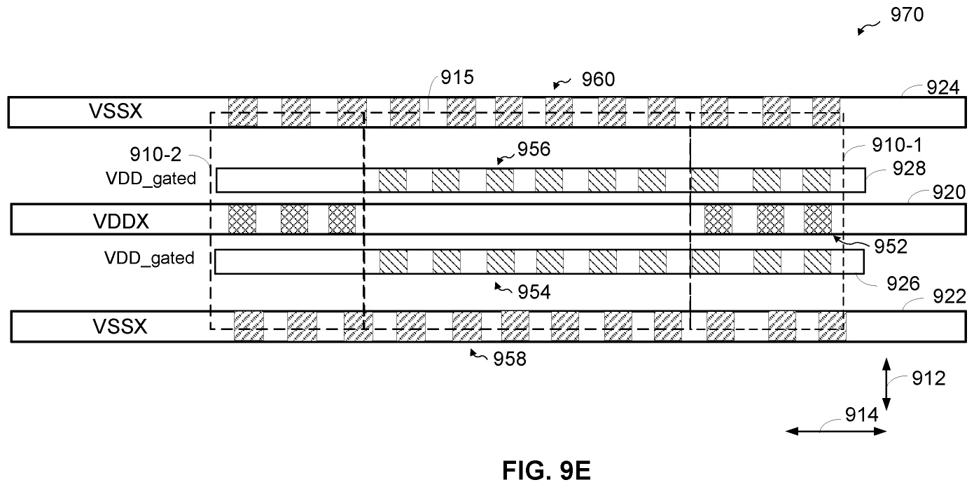

FIG. 9A shows a top view of an example of a layout 905 that may be used for the cell 710 or the cell 820 according to certain aspects. In this example, the layout 905 includes a first region 910 (i.e., first area) on the chip, and a second region 915 (i.e., second area) on the chip. The first region 910 may include the switch 860 (e.g., PFET 865), the switch 715, the switch 790, the clamp 770, and/or the clamp 880. Thus, the switch 860 (e.g., PFET 865), the switch 715, the switch 790, the clamp 770, and/or the clamp 880 may be laid out within the first region 910. The clamp 730 and/or clamps 870-1 to 870-4 may be laid out in the first region 910 near the switch 715, 790, or 860, or laid out in the second region 915 near the outputs being clamped. For case of illustration, the switch 860 (e.g., PFET 865), the switch 715, the switch 790, the clamp 770, the clamp 730, the clamps 870-1 to 870-4, and/or the clamp 880 are not explicitly shown in FIG. 9A.

The second region 915 may include gated circuits including the flip-flops 830-1 to 830-4 and/or the circuit 720. Thus, the flip-flops 830-1 to 830-4 and/or circuit 720 may be laid out within the second region 915. For ease of illustration, the flip-flops 830-1 to 830-4 and/or circuit 720 are not explicitly shown in FIG. 9A.

The layout 905 also includes a supply rail 920 extending in direction 914. The supply rail 920 may be formed from metal layer M0 or another metal layer using lithography and etching. The supply rail 920 may correspond to the rail 825, the second rail 797, or the external supply rail discussed above. The layout 905 also includes ground rails 922 and 924 extending in direction 914. The ground rails 922 and 924 may be formed from metal layer M0 or another metal layer using lithography and etching. The layout 905 also includes gated rails 926 and 928 extending in direction 914. The gated rails 926 and 928 may correspond to the node 828 or the node 776 discussed above. The gated rails 926 and 928 may be formed from metal layer M0 or another metal layer using lithography and etching.

In certain aspects, the switch 860 (e.g., PFET 865) or the switch 715 is coupled between the supply rail 920 (e.g., vddx) and the gated rail 926 (e.g., vdd_gated). For the example where the switch 860 includes the PFET 865, one or more of the vias 940 may be coupled between the source of the PFET 865 and the supply rail 920, and one or more of the vias 942 may be coupled between the drain of the PFET 965 and the gated rail 926. In FIG. 9A, the vias are depicted as shaded squares. For the example where the switch 715 includes the PFET 718, one or more of the vias 940 may be coupled between the source of the PFET 718 and the supply rail 920, and one or more of the vias 942 may be coupled between the drain of the PFET 718 and the gated rail 926.

For the example where the cell 820 includes the clamp 880, the clamp 880 may be coupled between the gated rail 926 and the ground rail 922. For the example where the clamp 880 includes the NFET 886, one or more of the vias 942 may be coupled between the drain of the NFET 886 and the gated rail 926, and one or more of the vias 944 may be coupled between the source of the NFET 886 and the ground rail 922.

For the example where the cell 710 includes the clamp 770, the clamp 770 may be coupled between the gated rail 926 and the ground rail 922. For the example where the clamp 770 includes the NFET 778, one or more of the vias 942 may be coupled between the drain of the NFET 778 and the gated rail 926, and one or more of the vias 944 may be coupled between the source of the NFET 778 and the ground rail 922.

In certain aspects, the flip-flops 830-1 to 830-4 or the circuit 720 may be coupled between the gated rail 928 (e.g., vdd_gated) and the ground rail 924. For example, one or more of the vias 946 may be coupled between the flip-flops 830-1 to 830-4 and the gated rail 928, and one or more of the vias 948 may be coupled between the flip-flops 830-1 to 830-4 and the ground rail 924. In another example, one or more of the vias 946 may be coupled between the circuit 720 and the gated rail 928, and one or more of the vias 948 may be coupled between the circuit 720 and the ground rail 924. In FIG. 9A, the vias are depicted as shaded squares.

The layout 905 may also include a first metal routing 930 and a second metal routing 932 extending in direction 912, which is perpendicular to direction 914. Each of the metal routings 930 and 932 may be formed form metal layer M1 or higher metal layer using lithography and etching. In this example, the metal routings 930 and 932 are used to couple the gated rail 926 to the gated rail 928. The metal routings 930 and 932 may be coupled to the gated rail 926 by vias (not shown) between the gated rail 926 and the metal routings 930 and 932, and the metal routings 930 and 932 may be coupled to the gated rail 928 by vias (not shown) between the gated rail 928 and the metal routings 930 and 932.

FIG. 9B shows an example in which the layout 905 include a third region 972 for the layout of a second cell. The second cell may be include a logic cell, a demultiplexer cell, a flip-flop cell, or another cell (e.g., from a standard cell library). The second cell may include one or more transistors that may be arranged to perform one or more functions. For ease of illustration, the layout of the individual transistors in the second cell are not explicitly shown in FIG. 9B.

In this example, the ground rails 924 and 922 extend in the direction 914 to provide ground rails for the second cell laid out in the third region 972. Also, in this example, the layout 905 includes supply rail 980 to provide the second cell with a supply voltage. In the example shown in FIG. 9B, the supply rail 980 extends in direction 914, and the supply rail 980 is aligned with the gated rail 928 in direction 912.

In this example, the supply rail 980 and the gated rail 928 may be formed from a common metal line (e.g., formed from metal M0) extending in direction 914, in which common metal line is cut 990 between the second cell and the cell 710 or 820 during fabrication to provide the supply rail 980 and the gated rail 928. The cut 990 electrically decouples the supply rail 980 and the gated rail 928, allowing the supply rail 980 and the gated rail 928 to be at different potentials. Cutting the metal line to form the supply rail 980 for the second cell and the gated rail 928 for the cell 710 or 820 reduces costs and area compared with using a separate metal line for the gated rail 928.

In another implementation, the supply rail 980 and the gated rail 928 may be formed from two separate metal lines (not shown) that are spaced apart in direction 912. In this example, the supply rail 980 may extend in direction 914 over the cell 710 or 820.

FIG. 9C shows a top view of an exemplary layout 908 in which the second region 915 in FIG. 9A is split into a first portion 915-1 and a second portion 915-2. In this example, the layout 908 includes another supply rail 934 extending in direction 914 across the second portion 915-2 of the second region 915.

The layout 908 may be used for the exemplary implementation of the cell 820 shown in FIG. 8B in which the master latches 840-1 to 840-4 are coupled to the node 828 (e.g., vdd_gated), and the slave latches 850-1 to 850-4 are coupled to the rail 825 (e.g., vddx). In this example, the master latches 840-1 to 840-4 may be located within the first portion 915-1 of the second region 915, and the slave latches 850-1 to 850-4 may be located in the second portion 915-2 of the second region 915. In certain aspects, the master latches 840-1 to 840-4 are coupled between the gated rail 928 (e.g., vdd_gated) and the ground rail 924. For example, one or more of the vias 946 may be coupled between the master latches 840-1 to 840-4 and the gated rail 928, and one or more of the vias 948 may be coupled between the master latches 840-1 to 840-4 and the ground rail 924.

The slave latches 850-1 to 850-4 may be coupled between the supply rail 934 and the ground rail 924. For example, one or more of the vias 936 may be coupled between the slave latches 850-1 to 850-4 and the supply rail 934, and one or more of the vias 948 may be coupled between the slave latches 850-1 to 850-4 and the ground rail 924. In FIG. 9C, the vias are depicted as shaded squares.

The switch 860 may be coupled between the supply rail 920 and the gated rail 926 in the manner discussed above with reference to FIG. 9A. The gated rail 926 may be coupled to the gated rail 928 by the metal routing 930 as discussed above with reference to FIG. 9A.

It is to be appreciated that the gated rail 928 may extend across the second portion 915-2 of the second region 915. It is also to be appreciated that the supply rail 934 may extend across the first portion 915-1 of the second region 915 in some implementations, as shown in the example in FIG. 9C. For implementations including the switch 810 between the cell 820 and the first rail (also referred to as external rail), the switch 810 (not shown in FIG. 9C) may be coupled between the supply rail 934 and the first rail.

FIG. 9D shows another example of a layout 950 that may be used for the cell 710 or the cell 820 according to certain aspects. In this example, the first region 910 and the second region 915 are located side-by-side. As discussed above, the first region 910 may include the switch 860 (e.g., PFET 865), the switch 715, the clamp 770, and/or the clamp 880, and the second region 915 may include gated circuits including the flip-flops 830-1 to 830-4 and/or the circuit 720. The layout 950 also includes the supply rail 920, the ground rails 922, 924, and the gated rails 926 and 928 extending in direction 914. In the example shown in FIG. 9D, the gated rails 926 and 928 extend across the first region 910 and the second region 915.

In certain aspects, the switch 860 (e.g., PFET 865) or the switch 715 is coupled between the supply rail 920 (e.g., vddx) and the gated rail 926 (e.g., vdd_gated) and/or between the supply rail 920 and the gated rail 928. For the example where the switch 860 includes the PFET 865, one or more of the vias 952 may be coupled between the source of the PFET 865 and the supply rail 920. One or more of the vias 954 may be coupled between the drain of the PFET 865 and the gated rail 926, and/or one or more of the vias 956 may be coupled between the drain of the PFET 865 and the gated rail 928. For the example where the switch 715 includes the PFET 718, one or more of the vias 952 may be coupled between the source of the PFET 718 and the supply rail 920. One or more of the vias 954 may be coupled between the drain of the PFET 718 and the gated rail 926, and/or one or more of the vias 956 may be coupled between the drain of the PFET 718 and the gated rail 928.

For the example where the cell 820 includes the clamp 880, the clamp 880 may be coupled between the gated rail 926 and the ground rail 922 and/or between the gated rail 928 and the ground rail 924. For the example where the clamp 880 includes the NFET 886, one or more of the vias 954 may be coupled between the drain of the NFET 886 and the gated rail 926, and one or more of the vias 958 may be coupled between the source of the NFET 886 and the ground rail 922. In another example, one or more of the vias 956 may be coupled between the drain of the NFET 886 and the gated rail 928, and one or more of the vias 960 may be coupled between the source of the NFET 886 and the ground rail 924.

In certain aspects, the flip-flops 830-1 to 830-4 or the circuit 720 may be coupled between the gated rail 928 (e.g., vdd_gated) and the ground rail 924. For example, one or more of the vias 956 may be coupled between the flip-flops 830-1 to 830-4 and the gated rail 928, and one or more of the vias 960 may be coupled between the flip-flops 830-1 to 830-4 and the ground rail 924. In another example, one or more of the vias 954 may be coupled between the flip-flops 830-1 to 830-4 and the gated rail 926, and one or more of the vias 958 may be coupled between the flip-flops 830-1 to 830-4 and the ground rail 922. In another example, one or more of the vias 956 may be coupled between the circuit 720 and the gated rail 928, and one or more of the vias 960 may be coupled between the circuit 720 and the ground rail 924. In another example, one or more of the vias 954 may be coupled between the circuit 720 and the gated rail 926, and one or more of the vias 958 may be coupled between the circuit 720 and the ground rail 922.

FIG. 9E shows an exemplary layout 970 in which the first region 910 in FIG. 9D is split into a first portion 910-1 and a second portion 910-2. In this example, the second region 915 is located between the first portion 910-1 of the first region 910 and the second portion 910-2 of the first region 910. In this example, the switch 860 or the switch 715 may be located in one of the portions 910-1 and 910-2 of the first region 910. Also, the clamp 880 or the clamp 770 may be located in one of the portions 910-1 and 910-2 of the first region 910.

FIG. 10A shows an example in which the chip includes a first dummy gate 1010 and a second dummy gate 1015 that define boundaries of the cell 710 according to certain aspects. Each of the dummy gates 1010 and 1015 (e.g., polysilicon gate, poly over diffusion edge (PODE), etc.) does not function as a gate of an active device (e.g., transistor) in the cell 710. In the example shown in FIG. 10A, the dummy gates 1010 and 1015 are elongated and extend in direction 912. The first dummy gate 1010 abuts a first side 1020 of the cell 710, the second dummy gate 1015 abuts a second side 1025 of the cell 710, and the first side 1020 and the second side 1025 are opposing sides. In other words, the cell 710 is bounded between the first and second dummy gates 1010 and 1015.

In this example, the circuit 720, the switch 715, and the clamp 730 in the cell 710 are located between the first dummy gate 1010 and the second dummy gate 1015 defining the side boundaries of the cell 710. For the implementations where the layout of the cell 710 includes the regions 910 and 915, the regions 910 and 915 are located between the first dummy gate 1010 and the second dummy gate 1015. It is to be appreciated that the present disclosure is not limited to this example, and that the boundaries of the cell 710 may be defined by other types of physical structures.

Although one cell 710 is shown in FIG. 10A, it is to be appreciated that the chip may include multiple instances of the cell 710 (e.g., cells 710-1 and 710-n). In this case, the chip may include multiple instances of the dummy gates 1010 and 1015, in which each instance of the cell 710 is bounded between a respective instance of the dummy gates 1010 and 1015.

FIG. 10B shows an example in which the chip includes a first dummy gate 1030 and a second dummy gate 1035 that define boundaries of the cell 820 according to certain aspects. Each of the dummy gates 1010 and 1015 (e.g., polysilicon gate, poly over diffusion edge (PODE), etc.) does not function as a gate of an active device (e.g., transistor) in the cell 820. In the example shown in FIG. 10B, the dummy gates 1030 and 1035 are elongated and extend in direction 912. The first dummy gate 1030 abuts a first side 1040 of the cell 820, the second dummy gate 1035 abuts a second side 1045 of the cell 820, and the first side 1040 and the second side 1045 are opposing sides. In other words, the cell 820 is bounded between the first and second dummy gates 1030 and 1035.

In this example, the flip-flops 830-1 to 830-4 and the switch 860 in the cell 820 are located between the first dummy gate 1030 and the second dummy gate 1035 defining the side boundaries of the cell 820. For the implementations where the layout of the cell 820 includes the regions 910 and 915, the regions 910 and 915 are located between the first dummy gate 1030 and the second dummy gate 1035. It is to be appreciated that the present disclosure is not limited to this example, and that the boundaries of the cell 820 may be defined by other types of physical structures.

Although one cell 820 is shown in FIG. 10B, it is to be appreciated that the chip may include multiple instances of the cell 820 (e.g., cells 820-1 to 820-m). In this case, the chip may include multiple instances of the dummy gates 1030 and 1035, in which each instance of the cell 820 is bounded between a respective instance of the dummy gates 1030 and 1035.

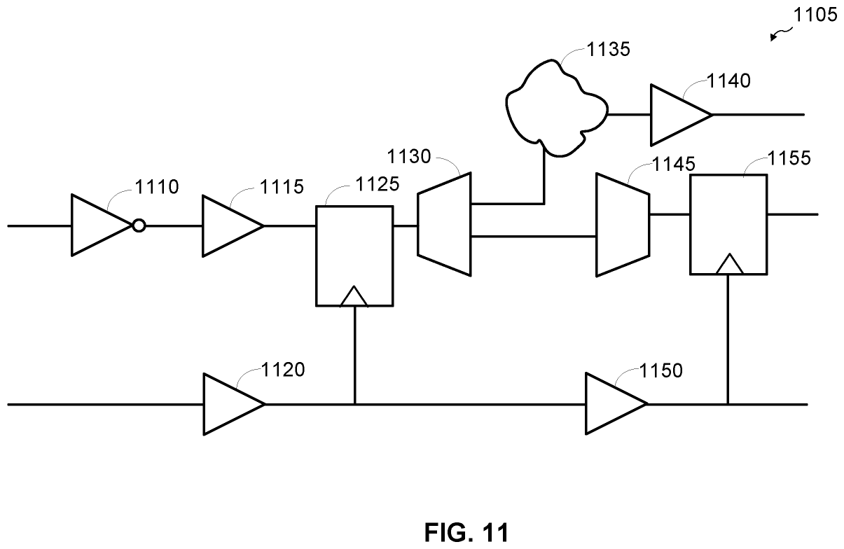

FIG. 11 shows an example of a system 1105 in which cells according to certain aspects of the present disclosure may be used. In this example, the system 1105 may include an inverter 1110, a first flip-flop 1125, a multiplexer 1130, combinational logic 1135, a demultiplexer 1145, a second flip-flop 1155, a first buffer 1115, a second buffer 1120, a third buffer 1140, and a fourth buffer 1150. However, it is to be appreciated that the system 1105 is not limited to the example shown in FIG. 11. For example, one or more of the circuits in FIG. 11 may be omitted from the system 1105 and/or one or more additional circuits may be added to the system 1105.

In this example, the inverter 1110, a first flip-flop 1125, a multiplexer 1130, combinational logic 1135, a demultiplexer 1145, a second flip-flop 1155, a first buffer 1115, a second buffer 1120, a third buffer 1140, and a fourth buffer 1150 may each be implemented in a standard cell defined by a standard cell library, in which the cells may be coupled by metal routing to implement the system 1105 on a chip.

In certain aspects, some or all of the inverter 1110, a first flip-flop 1125, a multiplexer 1130, combinational logic 1135, a demultiplexer 1145, a second flip-flop 1155, a first buffer 1115, a second buffer 1120, a third buffer 1140, and a fourth buffer 1150 may be implemented using an instance of the cell 710 or an instance of the cell 820 according to certain aspects. Because each instance of the cell 710 and each instance of the cell 820 includes an internal switch (e.g., switch 715 or 860) and/or an internal clamp (e.g., clamp 730, 770, 870, and/or 880), using instances of the cell 710 and/or instances of the cell 820 in the system 1105 allows the system 1105 to employ fine power gating (e.g., without the need to lay out separate switches and/or isolation cells for the system 1105).

It is to be appreciated that not all of the circuits in the system 1105 need to be power gated to reduce leakage current. For example, the inverter 1110 may be implemented in an instance of the cell 710 that includes the switch 715 and the clamp 730 while the first buffer 1115 may be implemented in a cell that does not include an internal switch or clamp. In this example, the inverter 1110 may be configured to clamp the output of the inverter 1110 low using the clamp 730 when the inverter 1110 is power gated. The low output of the inverter 1110 clamps the input of the first buffer 1115 low, which may place the first buffer 1115 in a state that prevent leakages current in the first buffer 1115. For example, clamping the input of the first buffer 1115 low may turn off a transistor in the first buffer 1115 (e.g., an NFET with a gate coupled to the input of the first buffer 1115), which prevents leakage current. Thus, by clamping the input of the first buffer 1115 to a known state (e.g., low) when the inverter 1110 is power gated, the inverter 1110 may prevent leakage current in the first buffer 1115. Therefore, the leakage current in the system 1105 may be reduced when the system 1105 is not active using a mix of cells with internal switches and clamps, and cells without internal switches or clamps.

Implementation examples are described in the following numbered clauses:
1. A cell, comprising:
   a circuit having an input and an output;
   a switch coupled between a supply rail and the circuit, wherein the switch is configured to receive an enable signal, turn on when the enable signal has a first logic value, and turn off when the enable signal has a second logic value; and
   a first clamp coupled to the output of the circuit, wherein the first clamp is configured to clamp the output of the circuit when the enable signal has the second logic value.
2. The cell of clause 1, wherein the circuit comprises a logic gate.
3. The cell of clause 1 or 2, wherein the first clamp is configured to clamp the output of the circuit high when the enable signal has the second logic value.
4. The cell of clause 1 or 2, wherein the first clamp is configured to clamp the output of the circuit low when the enable signal has the second logic value.
5. The cell of any one of clauses 1 to 4, wherein the switch comprises a first p-type field effect transistor (PFET) having a gate configured to receive the enable signal, a source coupled to the supply rail, and a drain coupled to the circuit.
6. The cell of clause 5, wherein:
   the first clamp comprises a second PFET having a gate, a source coupled to the supply rail, and a drain coupled to the output of the circuit; and
   the cell further comprises an inverter coupled between the gate of the first PFET and the gate of the second PFET.
7. The cell of any one of clauses 1 to 4, wherein:
   the switch comprises a p-type field effect transistor (PFET) having a gate configured to receive the enable signal, a source coupled to the supply rail, and a drain coupled to the circuit; and
   the first clamp comprises an n-type field effect transistor (NFET) having a gate coupled to the gate of the PFET, a drain coupled to the output of the circuit, and a source coupled to a ground.
8. The cell of any one of clauses 1 to 4, further comprising a second clamp coupled to a node between the switch and the circuit, wherein the second clamp is configured to clamp the node low when the enable signal has the second logic value.
9. The cell of clause 8, wherein:
   the switch comprises a p-type field effect transistor (PFET) having a gate configured to receive the enable signal, a source coupled to the supply rail, and a drain coupled to the circuit; and
   the second clamp comprises an n-type field effect transistor (NFET) having a gate coupled to the gate of the PFET, a drain coupled to the node, and a source coupled to a ground.
10. The cell of clause 8, wherein:
   the switch comprises a p-type field effect transistor (PFET) having a gate configured to receive the enable signal, a source coupled to the supply rail, and a drain coupled to the circuit; and
   the first clamp comprises a first n-type field effect transistor (NFET) having a gate coupled to the gate of the PFET, a drain coupled to the output of the circuit, and a source coupled to a ground; and
   the second clamp comprises a second NFET having a gate coupled to the gate of the PFET, a drain coupled to the node, and a source coupled to the ground.
11. The cell of any one of clauses 1 to 10, wherein:
   a first side of the cell abuts a first dummy gate;
   a second side of the cell abuts a second dummy gate; and
   the first side and the second side are opposing sides.
12. A cell, comprising:
   a circuit having an input and an output;
   a switch coupled between the circuit and a ground, wherein the switch is configured to receive an enable signal, turn on when the enable signal has a first logic value, and turn off when the enable signal has a second logic value; and
   a first clamp coupled to the output of the circuit, wherein the first clamp is configured to clamp the output of the circuit when the enable signal has the second logic value.
13. The cell of clause 12, wherein the switch comprises a first n-type field effect transistor (NFET) having a gate configured to receive the enable signal, a drain coupled to the circuit, and a source coupled to the ground.
14. The cell of clause 13, wherein:
   the first clamp comprises a second NFET having a gate, a drain coupled to the output of the circuit, and a source coupled to the ground; and
   the cell further comprises an inverter coupled between the gate of the first NFET and the gate of the second NFET.
15. The cell of clause 12, wherein:
   the switch comprises an n-type field effect transistor (NFET) having a gate configured to receive the enable signal, a drain coupled to the circuit, and a source coupled to the ground; and
   the first clamp comprises a p-type field effect transistor (PFET) having a gate coupled to the gate of the NFET, a source coupled to a supply rail, and drain coupled to the output of the circuit.
16. The cell of any one of clauses 12 to 15, wherein:
   a first side of the cell abuts a first dummy gate;
   a second side of the cell abuts a second dummy gate; and
   the first side and the second side are opposing sides.
17. A cell, comprising:
   one or more flip-flops; and
   a switch coupled between a supply rail and the one or more flip-flops, wherein the switch is configured to receive an enable signal, turn on when the enable signal has a first logic value, and turn off when the enable signal has a second logic value.
18. The cell of clause 17, wherein:
   each of the one or more flip-flops comprises a respective master latch and a respective slave latch;
   the switch is coupled between the supply rail and the master latch of each of the one or more flip-flops; and
   the slave latch of each of the one or more flip-flops is coupled to the supply rail.
19. The cell of clause 17 or 18, further comprising a clamp coupled to a node between the switch and the one or more flip-flops, wherein the clamp is configured to clamp the node low when the enable signal has the second logic value.
20. The cell of clause 19, wherein:
   the switch comprises a first p-type field effect transistor (PFET) having a gate configured to receive the enable signal, a source coupled to the supply rail, and a drain coupled to the one or more flip-flops; and
   the clamp comprises an n-type field effect transistor (NFET) having a gate coupled to the gate of the PFET, a drain coupled to the node, and a source coupled to a ground.
21. The cell of any one of clauses 17 to 20, further comprising one or more clamps, wherein each of the one or more clamps is coupled to an output of a respective one of the one or more flip-flops, and each of the one or more clamps is configured to clamp the output of the respective one of the one or more flip-flops low when the enable signal has the second logic value.
22. The cell of clause 21, wherein:
   the switch comprises a first p-type field effect transistor (PFET) having a gate configured to receive the enable signal, a source coupled to the supply rail, and a drain coupled to the one or more flip-flops; and
   each of the one or more clamps comprises a respective n-type field effect transistor (NFET) having a gate coupled to the gate of the PFET, a drain coupled to the output of the respective one of the one or more flip-flops, and a source coupled to a ground.
23. The cell of any one of clauses 17 to 22, wherein:
   a first side of the cell abuts a first dummy gate;
   a second side of the cell abuts a second dummy gate; and
   the first side and the second side are opposing sides.
24. A chip, comprising:
   a first switch coupled between a first supply rail and a second supply rail;
   a first cell, comprising:
      a first circuit having an input and an output;
      a second switch coupled between the second supply rail and the first circuit, wherein the second switch is configured to receive a first enable signal, turn on when the first enable signal has a first logic value, and turn off when the first enable signal has a second logic value; and
      a first clamp coupled to the output of the first circuit, wherein the first clamp is configured to clamp the output of the first circuit when the first enable signal has the second logic value.
   a second cell, comprising:
      a second circuit having an input and an output;
      a third switch coupled between the second supply rail and the second circuit, wherein the third switch is configured to receive a second enable signal, turn on when the second enable signal has the first logic value, and turn off when the second enable signal has the second logic value; and
      a second clamp coupled to the output of the second circuit, wherein the second clamp is configured to clamp the output of the second circuit when the second enable signal has the second logic value.
25. The chip of claim 24, further comprising:
   a third cell, comprising:
      one or more flip-flops; and
      a fourth switch coupled between the second supply rail and the one or more flip-flops, wherein the fourth switch is configured to receive a third enable signal, turn on when the third enable signal has the first logic value, and turn off when the third enable signal has the second logic value.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A cell, comprising:
a circuit having an input and an output;
a switch coupled between a supply rail and the circuit, wherein the switch is configured to receive an enable signal, turn on when the enable signal has a first logic value, and turn off when the enable signal has a second logic value; and
a first clamp coupled to the output of the circuit, wherein the first clamp is configured to clamp the output of the circuit when the enable signal has the second logic value.

2. The cell of claim 1, wherein the circuit comprises a logic gate.

3. The cell of claim 1, wherein the first clamp is configured to clamp the output of the circuit high when the enable signal has the second logic value.

4. The cell of claim 1, wherein the first clamp is configured to clamp the output of the circuit low when the enable signal has the second logic value.

5. The cell of claim 1, wherein the switch comprises a first p-type field effect transistor (PFET) having a gate configured to receive the enable signal, a source coupled to the supply rail, and a drain coupled to the circuit.

6. The cell of claim 5, wherein:
the first clamp comprises a second PFET having a gate, a source coupled to the supply rail, and a drain coupled to the output of the circuit; and
the cell further comprises an inverter coupled between the gate of the first PFET and the gate of the second PFET.

7. The cell of claim 1, wherein:
the switch comprises a p-type field effect transistor (PFET) having a gate configured to receive the enable signal, a source coupled to the supply rail, and a drain coupled to the circuit; and
the first clamp comprises an n-type field effect transistor (NFET) having a gate coupled to the gate of the PFET, a drain coupled to the output of the circuit, and a source coupled to a ground.

8. The cell of claim 1, further comprising a second clamp coupled to a node between the switch and the circuit, wherein the second clamp is configured to clamp the node low when the enable signal has the second logic value.

9. The cell of claim 8, wherein:
the switch comprises a p-type field effect transistor (PFET) having a gate configured to receive the enable signal, a source coupled to the supply rail, and a drain coupled to the circuit; and
the second clamp comprises an n-type field effect transistor (NFET) having a gate coupled to the gate of the PFET, a drain coupled to the node, and a source coupled to a ground.

10. The cell of claim 8, wherein:
the switch comprises a p-type field effect transistor (PFET) having a gate configured to receive the enable signal, a source coupled to the supply rail, and a drain coupled to the circuit; and
the first clamp comprises a first n-type field effect transistor (NFET) having a gate coupled to the gate of the PFET, a drain coupled to the output of the circuit, and a source coupled to a ground; and
the second clamp comprises a second NFET having a gate coupled to the gate of the PFET, a drain coupled to the node, and a source coupled to the ground.

11. The cell of claim 1, wherein:
a first side of the cell abuts a first dummy gate;
a second side of the cell abuts a second dummy gate; and
the first side and the second side are opposing sides.

12. A cell, comprising:
a circuit having an input and an output;
a switch coupled between the circuit and a ground, wherein the switch is configured to receive an enable signal, turn on when the enable signal has a first logic value, and turn off when the enable signal has a second logic value; and
a first clamp coupled to the output of the circuit, wherein the first clamp is configured to clamp the output of the circuit when the enable signal has the second logic value.

13. The cell of claim 12, wherein the switch comprises a first n-type field effect transistor (NFET) having a gate configured to receive the enable signal, a drain coupled to the circuit, and a source coupled to the ground.

14. The cell of claim 13, wherein:
the first clamp comprises a second NFET having a gate, a drain coupled to the output of the circuit, and a source coupled to the ground; and
the cell further comprises an inverter coupled between the gate of the first NFET and the gate of the second NFET.

15. The cell of claim 12, wherein:
the switch comprises an n-type field effect transistor (NFET) having a gate configured to receive the enable signal, a drain coupled to the circuit, and a source coupled to the ground; and
the first clamp comprises a p-type field effect transistor (PFET) having a gate coupled to the gate of the NFET, a source coupled to a supply rail, and drain coupled to the output of the circuit.

16. The cell of claim 12, wherein:
a first side of the cell abuts a first dummy gate;
a second side of the cell abuts a second dummy gate; and
the first side and the second side are opposing sides.

17. A cell, comprising:
one or more flip-flops; and
a switch coupled between a supply rail and the one or more flip-flops, wherein the switch is configured to receive an enable signal, turn on when the enable signal has a first logic value, and turn off when the enable signal has a second logic value.

18. The cell of claim 17, wherein:
each of the one or more flip-flops comprises a respective master latch and a respective slave latch;
the switch is coupled between the supply rail and the master latch of each of the one or more flip-flops; and
the slave latch of each of the one or more flip-flops is coupled to the supply rail.

19. The cell of claim 17, further comprising a clamp coupled to a node between the switch and the one or more flip-flops, wherein the clamp is configured to clamp the node low when the enable signal has the second logic value.

20. The cell of claim 19, wherein:
the switch comprises a first p-type field effect transistor (PFET) having a gate configured to receive the enable signal, a source coupled to the supply rail, and a drain coupled to the one or more flip-flops; and
the clamp comprises an n-type field effect transistor (NFET) having a gate coupled to the gate of the PFET, a drain coupled to the node, and a source coupled to a ground.

21. The cell of claim 17, further comprising one or more clamps, wherein each of the one or more clamps is coupled to an output of a respective one of the one or more flip-flops, and each of the one or more clamps is configured to clamp the output of the respective one of the one or more flip-flops low when the enable signal has the second logic value.

22. The cell of claim 21, wherein:
the switch comprises a first p-type field effect transistor (PFET) having a gate configured to receive the enable signal, a source coupled to the supply rail, and a drain coupled to the one or more flip-flops; and
each of the one or more clamps comprises a respective n-type field effect transistor (NFET) having a gate coupled to the gate of the PFET, a drain coupled to the output of the respective one of the one or more flip-flops, and a source coupled to a ground.

23. The cell of claim 17, wherein:
a first side of the cell abuts a first dummy gate;
a second side of the cell abuts a second dummy gate; and
the first side and the second side are opposing sides.
